(19) United States
(12) Patent Application Publication
(10) Pub. No.: US 2024/0223145 A1
(43) Pub. Date: Jul. 4, 2024

(54) Articulating Sound Amplifier System

(71) Applicant: John Richard Shaffer, Henderson, NV (US)

(72) Inventor: John Richard Shaffer, Henderson, NV (US)

(73) Assignee: John Richard Shaffer, Henderson, NV (US)

(21) Appl. No.: 18/398,818

(22) Filed: Dec. 28, 2023

Related U.S. Application Data
(60) Provisional application No. 63/478,477, filed on Jan. 4, 2023.

(51) Int. Cl. H03F 3/68; H04R 1/02; H04R 1/32; H04R 3/12

(52) U.S. Cl. CPC H03F 3/68; H04R 1/025; H04R 1/323; H04R 3/12; H04R 2201/025

(57) ABSTRACT

The sound amplifier system disclosed herein can transmit discrete electronic output signals via discrete channels to different speaker types or different speaker sets. For example, in some situations a guitarist may want to play a clean tone through a speaker type designed to play clean tones. In other situations, a guitarist may want to play a distorted tone through a speaker type designed to play distorted tones. The sound amplifier system allows the guitarist to select which speaker type they wish to transmit their guitar output signal to depending on what sound they want to play. In addition, this disclosure also concerns various embodiments of a sound amplifier system which have articulating speakers that may be tilted vertically or horizontally.

### CROSS-REFERENCE TO RELATED APPLICATIONS

This application claims benefit of priority with U.S. Provisional Application Ser. No. 63/478,477, filed Jan. 4, 2023; the entire contents of which are hereby incorporated by reference.

### BACKGROUND

### Field of the Invention

The invention relates to sound amplifier systems and associated methods; more particularly, guitar amplifier systems having one or more different speaker types or different speaker sets connected to one or more discrete channel outputs of one or more amplifier channels as well as speaker systems having speakers that may be articulated to improve the sound output.

### Description of the Related Art

In some electric guitar amplifiers, there are multiple discrete channels which can be used by a guitar player. Various channels may be used in order to achieve different sounds. A channel utilizes settings on a guitar amplifier to configure a particular sound as opposed to another channel which might be configured to a different sound. For example, on one channel a guitar player might set what is called a “clean” tone. A clean tone is a tone that exhibits minimal perceivable distortion or breakup. A clean tone sound is much like hearing a guitar, electric or acoustic, acoustically, with no amplification.

On another channel, a guitar player might set up a “crunch” tone sound. This sound is reminiscent of distortion or crunch, much like the tones of hard rock music reminiscent of the music group, “AC/DC.” On yet a third channel, the guitar player might choose to set the volume louder or have a that channel have different bass, treble or mid-range settings. There are virtually endless ways for a guitar player to “set-up” their amp depending on the performance, the needs of a song, how the guitar player wants to practice, their own desires, etc.

The guitar player typically switches between these channels either by using a footswitch connected to the amplifier or by an electromechanical switch on the amplifier. When performing, guitar players routinely switch between a rhythm sound, set-up on one channel, and a solo or lead sound, set-up on another channel. It should be noted that it is common on many guitar amplifiers to allow the user to configure a “boost” to an existing channel. For example, a guitar amplifier might allow the guitar player to enable a volume boost or cut, or gain boost or cut, for a particular channel giving them even more options to achieve different tones and output volumes for the active channel.

Guitar amplifiers typically are configured with one, two, or four speakers either housed in an all-in-one enclosure, referred to as a combo amp, or configured with separate amplifier and speaker cabinet enclosures. Guitar amplifiers that have both their controls and the electronics housed together with the speakers are called “combo” amps. The amplifier controls and electronics within a combo amp are referred to as the “amplifier system” herein. Guitar amplifiers that have separate amplifier electronics and controls in one enclosure and a separate enclosure for the speakers are typically referred to as a head and cabinet configuration.

These amplifier systems can have multiple speaker cabinets. In the typical guitar amplifier set-up, the speakers in the combo amp configuration or in the head plus speaker cabinet configuration are the same type and receive the output signals regardless of which channel or boost setting is activated on the guitar amplifier controls (electronics). That means that even though the guitar player can switch between multiple channels producing different sounds or tones, they are still outputting sound from the different channels through the same speaker or speakers. This is one reason many guitar players use multiple guitar amplifiers.

A guitar player may use one particular guitar amplifier because it produces the “clean” tone better than another, through one type of speaker or speakers. Or they may use another guitar amplifier because it produces a better “crunch” tone through different type of speakers, etc. It is a well-understood, and a generally accepted fact amongst experts in the field of guitar amplification, that the particular speaker chosen for a guitar amplifier is largely responsible for the characteristic of the tone that emanates from the guitar amplifier. In other words, speakers designed for a clean tone are best suited for music requiring a clean, undistorted guitar sound. The same applies to music requiring a crunch tone or sound. It is widely accepted that the type of speaker alone may account for over 80% of the tone and overall sound output from the guitar amplifier system.

In the evolution of rock music from the 1950's to today, popular artists using certain brands of guitar amplifiers, which used certain speakers, started to imprint these particular sounds as benchmarks or defining tones that many novice guitar players wanted to copy and still do today. These defining tones carried with them the guitar amplifiers (and the speakers they used) that the artists used to get those tones. For example, Marshall® Amps became known for crunch tone and Fender® amps became known for clean tone. Each company uses a different electronic circuit than the other but more importantly, different speakers in their guitar amplifiers. This has created a conundrum for guitar players who are forced to purchase multiple different guitar amplifiers at significant cost in order to achieve those signature defining tones. Or, guitar players are forced to compromise the vintage tone sound and use other methods, such as modern effects pedals which connect into their guitar amplifier to digitally get different tones that the amplifier cannot reproduce on its own due to the limitation of having one or more of the same type of speakers for all channels of the guitar amp. This is a less than desirable situation as additional components adds additional cost and carrying requirements for the performing musician.

In addition, most guitar amplifiers are placed at floor level, whether in a room in a guitar player's home or on stage during a performance. Typically, the speakers in a combo guitar amplifier configuration or in a head plus speaker cabinet(s) configuration, have the face of the speaker at a 90-degree angle to the base of the enclosure. In a typical four speaker enclosure the configuration is that of 2 speakers, horizontally placed side by side in a bottom row, and two additional speakers, horizontally placed side by side (matching the horizontal placement of the bottom row of speakers) placed above the bottom two speakers in relatively the same plane. The two top horizontal set of speakers are sometimes angled upwards at less than 5 degrees from the base of the enclosure, providing an aesthetically pleasing “look” for the speaker cabinet. However, in most all cases, the projection of sound of a typical guitar amplifier is parallel to the base of the enclosure and in most all cases, parallel to the floor or ground the amplifier is placed.

Typically, guitar players stand when playing guitar, especially when on stage or performing in front of an audience or practicing in a band context. Most guitar amplifiers are placed on the ground with speakers (the speaker face) that are perpendicular to the ground. Thus, sound is projected at or near the player's ankles or at best, their legs. This is not optimal for hearing the sound from a guitar amplifier. It is well known to those who use guitar amplifiers that in order to hear a guitar amplifier's true tones, the guitar amplifier should be tilted upward, thereby tilting its speakers upwards, anywhere from 7 to 30 degrees. For years, guitar players have tilted their amplifiers back against a wall or other object in order to fully project the best tone from the guitar amplifier.

Another common problem with conventional amplifiers is that the controls are usually mounted to the upper front face of the guitar amplifier or on the top surface of the amplifier. This means when the amp is tilted, as described above, the controls are far away from the player. The position and location of the controls force the guitar player to step to the side and lean over to adjust the controls. The ergonomics of the guitar player adjusting their amplifier could be improved if the amplifier were to sit on the ground as designed yet project its sound upward (from the speakers).

This is a frustration commonly expressed by guitar players at all levels so much so that in the Fender® Musical Instruments Corporation went so far as to install movable metal “arms” on the sides of their Super Reverb® guitar amplifier which allowed the user to move the arms rearward a fixed amount in order to tilt the amplifier back so the sound would project upward. However, tilting an amplifier back against a wall or object can make it unsteady and may result in the amplifier crashing to the ground on its rear side, thus making the amp very susceptible to damaging the cosmetic features or the plethora of electronic components and vacuum tubes. Even with this solution, the controls are very far from the player.

Therefore, a need exists to have a guitar amplifier system, capable of switching channels which are configured with discrete signal outputs for at least two independent channels and which is configured to output those discrete channel signals to different speaker types or different sets of speakers so that the guitar player can faithfully get the desired tones they want from various channels on the guitar amplifier without having to use multiple guitar amplifiers or extraneous guitar effects pedals connected to their amplifier.

There also exists a need to have a guitar amplifier speaker cabinet or combo amplifier which is configured with the ability to vary the internal angle of the speakers contained within it, relative to the enclosure or speaker cabinet in order to project the sound for optimal audible results and yet allow the guitar combo amplifier or speaker cabinet to remain in a secure, non-tilted state resting on the floor or wherever surface it is placed on.

### SUMMARY

This disclosure concerns various embodiments of a sound amplifier system which can play different channels through different speakers or speaker sets. Discrete signal outputs of different channels provide different desired tones, and these different desired tones may be emitted from different speakers or speaker types which may be contained in one or more speaker cabinets or enclosures. This disclosure also concerns various embodiments of a sound amplifier system which has articulating speakers that may be tilted. The sound amplifier systems are electrically powered by a power supply which may provide AC or DC current.

The sound amplifier system, also referred to as “the system,” enables a user to configure the settings on an amplifier such that a variety of desired tones can be configured for different channels on the amplifier, and each channel's signal may be discretely output to different speaker types or speaker sets. The sound amplifier system described herein may be configured to have one or more speakers of the same type or different types, per channel output signal.

In yet another embodiment, the system could be configured to allow for one or more speakers contained in one or more speaker cabinets or enclosures, to be articulated relative to a horizontal up-down plane or a vertical left-right plane. This articulation could be configured to be fixed or be adjustable per user control. This embodiment could also be configured as described above, with discrete channel outputs be configured or routed to discrete speakers or speaker sets.

### BRIEF DESCRIPTION OF THE DRAWINGS

Other features, combinations, and embodiments will be appreciated by one having the ordinary level of skill in the art of sound amplifier systems, associated methods, and accessories upon a thorough review of the following details and descriptions, particularly when reviewed in conjunction with the drawings, wherein:

FIG. 1A shows a signal wiring schematic of the sound amplifier system in accordance with a first illustrated embodiment;

FIG. 1B shows a signal wiring schematic of the sound amplifier system in accordance with a second illustrated embodiment;

FIG. 1C shows a signal wiring schematic of the sound amplifier system in accordance with a third illustrated embodiment;

FIG. 1D shows a signal wiring schematic of the sound amplifier system in accordance with a fourth illustrated embodiment;

FIG. 2A shows a signal wiring schematic of the sound amplifier system in accordance with a fifth illustrated embodiment;

FIG. 2B shows a signal wiring schematic of the sound amplifier system in accordance with a sixth illustrated embodiment;

FIG. 2C shows a signal wiring schematic of the sound amplifier system in accordance with a seventh illustrated embodiment;

FIG. 2D shows a signal wiring schematic of the sound amplifier system in accordance with an eighth illustrated embodiment;

FIG. 3A shows a signal wiring schematic of the sound amplifier system in accordance with a ninth illustrated embodiment;

FIG. 3B shows a signal wiring schematic of the sound amplifier system in accordance with a tenth illustrated embodiment;

FIG. 3C shows a signal wiring schematic of the sound amplifier system in accordance with an eleventh illustrated embodiment;

FIG. 3D shows a signal wiring schematic of the sound amplifier system in accordance with a twelfth illustrated embodiment;

FIG. 4A shows a signal wiring schematic of the sound amplifier system in accordance with a thirteenth illustrated embodiment;

FIG. 4B shows a signal wiring schematic of the sound amplifier system in accordance with a fourteenth illustrated embodiment;

FIG. 4C shows a signal wiring schematic of the sound amplifier system in accordance with a fifteenth illustrated embodiment;

FIG. 4D shows a signal wiring schematic of the sound amplifier system in accordance with a sixteenth illustrated embodiment;

FIG. 5A shows a signal wiring schematic of the sound amplifier system in accordance with a seventeenth illustrated embodiment;

FIG. 5B shows a signal wiring schematic of the sound amplifier system in accordance with an eighteenth illustrated embodiment;

FIG. 5C shows a signal wiring schematic of the sound amplifier system in accordance with a nineteenth illustrated embodiment;

FIG. 5D shows a signal wiring schematic of the sound amplifier system in accordance with a twentieth illustrated embodiment;

FIG. 6 shows a front view of a sound amplifier system in accordance with a second illustrated embodiment;

FIG. 7 shows a front view of a sound amplifier system in accordance with a third illustrated embodiment;

FIG. 8 shows a front view of a sound amplifier system in accordance with a sixth illustrated embodiment;

FIG. 9 shows a front view of a speaker cabinet in accordance with a fifth illustrated embodiment;

FIG. 10A shows a left-right plane through a speaker cabinet;

FIG. 10B shows an up-down plane through a speaker cabinet;

FIG. 10C shows a front-back plane through a speaker cabinet;

FIG. 11A shows a front view of the sound amplifier system in accordance with a twenty-first illustrated embodiment;

FIG. 11B shows a front view of the sound amplifier system in accordance with a twenty-second illustrated embodiment;

FIG. 11C shows a front view of the sound amplifier system in accordance with a twenty-third illustrated embodiment;

FIG. 11D shows a front view of the sound amplifier system in accordance with a twenty-fourth illustrated embodiment;

FIG. 11E shows a front view of the sound amplifier system in accordance with a twenty-fifth illustrated embodiment;

FIG. 11F shows a front view of the sound amplifier system in accordance with a twenty-sixth illustrated embodiment;

FIG. 11G shows a front view of the sound amplifier system with the top half, bottom half, left half, and right half of the speaker baffle identified.

FIG. 12A shows a side section view of the sound amplifier system in accordance with a twenty-first illustrated embodiment;

FIG. 12B shows a side section view of the sound amplifier system in accordance with a twenty-second illustrated embodiment;

FIG. 12C shows a side section view of the sound amplifier system in accordance with a twenty-third illustrated embodiment;

FIG. 12D shows a side section view of the sound amplifier system in accordance with a twenty-fourth illustrated embodiment;

FIG. 12E shows a side section view of the sound amplifier system in accordance with a twenty-fifth illustrated embodiment;

FIG. 12F shows a side section view of the sound amplifier system in accordance with a twenty-sixth illustrated embodiment;

FIG. 13A shows a front view of the sound amplifier system in accordance with a twenty-seventh illustrated embodiment;

FIG. 14A shows a side section view of the sound amplifier system in accordance with a twenty-seventh illustrated embodiment;

FIG. 14B shows a side section view of the sound amplifier system in accordance with a twenty-seventh illustrated embodiment;

FIG. 14C shows a top section view of the sound amplifier system in accordance with a twenty-seventh illustrated embodiment;

FIG. 14D shows a top section view of the sound amplifier system in accordance with a twenty-seventh illustrated embodiment; and

FIG. 14E shows a top section view of the sound amplifier system in accordance with a twenty-seventh illustrated embodiment.

### DETAILED DESCRIPTION

For purposes of explanation and not limitation, details and descriptions of certain preferred embodiments are hereinafter provided such that one having ordinary skill in the art may be enabled to make and use the invention. These details and descriptions are representative only of certain preferred embodiments, however, a myriad of other embodiments which will not be expressly described will be readily understood by one having skill in the art upon a thorough review of the instant disclosure. Accordingly, any reviewer of the instant disclosure should interpret the scope of the invention only by the claims, as such scope is not intended to be limited by the embodiments described and illustrated herein.

The term “speaker” refers to any device with converts electrical energy to mechanical energy to produce a sound.

The term “speaker set” refers to two or more of the same type of speaker.

The terms “speaker cabinet,” “speaker cab,” “speaker enclosure,” “speaker cabinet enclosure,” and “speaker mount” are synonymous, and they refer to the overall structure onto which the speakers are mounted.

The term “baffle” refers to the substrate that holds the speaker or speakers within the speaker cabinet enclosure.

The terms “combo amp,” “combo amplifier,” or “all-in-one enclosure” refer to amplifiers that have both their controls and the electronics housed together with the speakers.

The term “amp system” refers to the amplifier controls and associated electronics within a combo amp.

The term “head and cabinet configuration” refers to an amplifier that has separate amplifier electronics and controls in one enclosure and a separate enclosure for the speakers.

The term “channels” refers to separate selectable settings on an amplifier to configure a particular sound as opposed to another channel which may be configured to a different sound.

The term “clean tone” refers to a tone that exhibits minimal distortion or breakup.

The term “crunch tone” refers to a sound that is reminiscent of audio distortion, much like the tones of hard rock music.

The terms “footswitch” or “switch” refers to the device which may change the selected channel or channels.

The term “signal input receiver” refers to the component of the amplifier or combo amp which receives the signal from the instrument. The signal input receiver may be a physical input jack where a cable may be plugged in, or it may be a wireless receiver which functions by receiving electro-magnetic waves such as radio waves, Bluetooth, voice activation.

The term “daisy chaining” refers to connecting multiple speakers, often in separate speaker cabinets, in parallel to receive the same output signal.

Unless explicitly defined herein, terms are to be construed in accordance with the plain and ordinary meaning as would be appreciated by one having skill in the art.

### General Description of Embodiments

In the exemplary embodiment, the sound amplifier system would be designed such that multiple channels may be configured to output the signal of each channel to one or more speaker cabinets with one or more different speaker types or different sets of speakers. A speaker set shall be defined as comprising two or more of the same type of speakers. Speaker cabinet(s) shall be synonymous with speaker cab(s), enclosure(s), or mount(s). The term “speaker” is used throughout this application out of convenience. Where the term “speaker” is used in this application, the reader may insert the following phrase “an electroacoustic transducer that converts an electrical audio signal into a corresponding sound.”

There is no limitation to the number of channels on the amplifier, and subsequently, the number of types of speakers or speaker sets that may be configured in the system. The system could include one speaker cabinet containing different speaker types or sets of speakers for each channel on the guitar amplifier. The system could then be configured to allow the user to switch channels, thus switching the output signal path to different speaker types or sets of speakers.

For example, a two-channel embodiment could utilize a four-speaker configuration such that two speakers could be activated (by the user switching channels on the guitar amplifier), for one channel and the other two different types of speakers activated for the other channel. The speaker sets could be arranged either diagonally, vertically, or horizontally, or in any other fashion as desired inside the speaker cabinet or enclosure.

In the above exemplary embodiment, the speakers or speaker sets inside each speaker cabinet could also be angled upward as to provide more sound at the proper listening level. The speakers could be configured to be articulated to achieve this angle individually or as part of a speaker baffle system contained inside a speaker cabinet. A baffle is the substrate that holds the speaker or speakers within the speaker cabinet enclosure. This upward angle of the speakers may be configured to be a fixed amount or be able to be varied by a means controlled by the user. The variable baffle system could be electromechanically controlled to vary the baffle angle containing the different speaker types or speaker sets and move the baffle upward or downward to any degree within a range compatible with the enclosure and to the user's selection. Sound amplifier systems which have speakers that may tilt vertically, horizontally, or both vertically and horizontally are referred to as articulating speaker systems.

Expanding on the previous embodiment, in the sound amplifier system utilizing the one or more speaker cabinets with one or more speaker types or speaker sets, the angle could be fixed inside the one or more speaker cabinets, or it could be variable by the user. This variability in the one or more speakers in the one or more speaker cabinets could be articulated manually by the user by a system on the speaker cabinet or by an electronic motor system inside the speaker cabinet and activated via switch on the guitar amplifier head, the speaker cabinet itself or remotely by a device which may communicate with the electronic motor system. This communication could be by cable, wi-fi, or Bluetooth and any other means known to those in the art or remote motor control.

In the embodiment comprising two speakers (either different types or of the same type) within one enclosure, the baffle system could be two independent systems, each containing one speaker. In this embodiment the user could move each speaker independently from one another within the enclosure either articulating the speaker upwards or downwards and/or moving the speaker horizontally outwards or inwards.

For example, by changing the angle of the different speaker types or speaker sets inside the speaker cabinet, upward or downward (upward being the speaker tilting back) to produce an angle greater or less than horizontal. The vertical speaker angle for a sound amplification system having articulating speakers may range between 0 and +30 degrees above a horizontal up/down plane. The horizontal speaker angle for a sound amplification system having articulating speakers may range between −30 degrees to the left and +30 degrees to the right with respect to a left-right plane.

A speaker baffle, onto which one or more articulating speakers are mounted, may attached or coupled to a speaker angle adjusting system. A speaker angle adjusting system facilitates the articulation of a speaker baffle. In some embodiments, the speaker angle adjusting system may comprise hinge or a system of hinges which have an axis of rotation. In some embodiments, the speaker angle adjusting system may comprise a living hinge or a system of living hinges. In some embodiments, the speaker angle adjusting system may comprise a system of gears, shafts, bearings, cams or some combination thereof.

In the example of a speaker articulated upward, the speakers project the sound up and out toward a user or listener's ears. Another benefit of angling the speakers upward inside a guitar cabinet is that the guitar player can better hear his own tone and the many nuances of playing. Yet another benefit of articulating the speakers or speaker sets upward inside a speaker cabinet is that the sound may better project out of the speaker cabinet or enclosure to fill the room or space it is in. For example, the articulating speaker system would be useful for an electric guitarist playing with other musicians in an orchestral pit near the front of a stage where the musicians are lower than the audience.

In another embodiment, the sound amplifier system could be configured to have two or more different speaker sets within a speaker cabinet or combo guitar amplifier. For example, the system could be configured to have a speaker cabinet with two different type speaker sets. The speaker cabinet could be configured to allow independent connections to the different speaker sets contained therein. In this example, each speaker set could be connected to one or more discrete channel signal outputs on the guitar amplifier. In another example, the speaker cabinet or combo guitar amplifier could be configured to contain multiple speaker types. The speaker cabinet could be configured to allow independent connections to the different speaker types contained therein.

In yet another embodiment, the sound amplifier system could be configured to have different speaker types within a speaker set and the sound amplifier system could be configured with two or more speaker cabinets. In the example of a guitar amplifier system with two speaker cabinets containing two speakers each, each cabinet could be configured to contain different speaker types as opposed to speaker set (which contains the same speaker types). This configuration would allow for different channel signal outputs to be connected to the different speaker cabinets such that when the user selected one channel on the guitar amplifier, the user would hear sound from one speaker contained within the first speaker cabinet, and one speaker of the same type, contained within the second speaker cabinet.

The “active speakers” could be of the same type or different types. This configuration would allow the user to have their sound coming from both speaker cabinets at any given time regardless of the channel the user selected, but still achieve the desired result of having discrete channel signal outputs configured to different speaker types.

In another embodiment, the sound amplifier system could be configured to have different speaker types or speaker sets of different sizes. For example, in one or more speaker cabinets connected to the guitar amplifier, the speaker, speakers, or speaker sets could comprise speakers of different sizes or diameters as well as different or the same speaker types. This configuration would allow for even more tonal shaping of the user's sound. In this type of configuration, each speaker cabinet could be configured with a removable baffle which the user could then interchange depending upon their needs. This would allow the user to configure different baffles for different applications and easily interchange them.

The invention described herein would not be limited by any type of removable speaker system constructed in the one or more speaker cabinets. Also, the removable baffle system may be combined with the aforementioned variable angle baffle configuration.

In another embodiment, the sound amplifier system could be configured to have a speaker cabinet or speaker cabinets constructed of different materials and different configurations and combined with the aforementioned embodiments. For example, one or more speaker cabinets could be constructed to have a closed back while one or more other speaker cabinets could have an open back. This variable configuration would allow different speakers to utilize different inherent sound properties in order to enhance the user's sound output even further. There is no limitation on the size and shape or internal or external construction of the one or more speaker cabinets utilizing the invention described herein. The closed back configuration and open back configuration may be configured to be variable as well.

In another embodiment, the rear of the speaker cabinet(s) or guitar combo amplifier could be comprised of a moveable part that would move vertically to reveal an opening thus yielding the above mentioned open back cabinet. This opening could be configured to be of any size or shape within the enclosures rear outer perimeter dimensions. The opening could be manually actuated, or electro mechanically actuated by the user using techniques and systems known to those in the art.

In another embodiment, the sound amplifier system could be configured to allow the one or more speaker cabinets to have the one or more speaker types or speaker sets that are mounted, fixed, or movable, in different vertical and horizontal planes relative to one another. Sound amplifier systems having these tilting or rotating functionalities are called articulating speaker systems. Articulating speaker systems allow a user to configure the speaker cabinets so as to allow speakers with different sonic and tonal characteristics to be placed as desired in order to enhance the sound emanating from the speaker cabinet.

Furthermore, the sound amplifier system could be configured to allow the one or more speaker cabinets to have the one or more speaker types or speaker sets that are mounted, fixed or removable, configured on different angles or planes relative to one another. There is no limit to the direction or angle of the speaker or speakers relative to the listener and relative to other speaker types, speaker sets or speaker cabinets in the sound amplifier system described herein. Furthermore, by combining the above embodiments, the sound amplifier system could be configured to have on one or more speaker cabinets with one or more speaker types or speaker sets such that there could be speakers at different angles and in different planes relative to one another, the user, or any other point of reference.

In yet another embodiment, the sound amplifier system could be configured to provide different power amounts to different channel outputs. For example, one or more channel signal outputs could be configured to allow different wattage or amounts of power to be connected to the one or more speaker cabinets housing the one or more speaker types or speaker sets. This would allow a user to utilize different power rated speakers within the sound amplifier system.

In yet another embodiment, the sound amplifier system could be configured with the one or more speaker cabinets having one or more speaker types or speaker sets and configured such that the independent guitar amplifier channels may be configured to be switchable by the user. This would allow the user to change speaker types or speaker sets for a given amplifier channel. An application of such a system would allow a user to change the speaker/channel configuration during a performance or in-between different songs, etc.

There is no limitation on the number of channels and/or outputs a guitar amplifier may be configured for. Therefore, if the number of discrete speakers is less than the number of channels, some channels could be configured to send their output signals to the same speaker type or speaker sets. For example, in a guitar amplifier system that has three discrete channel outputs and in which the guitar amplifier system has two speaker cabinets each having one or more speaker types or speaker sets, any two of the three channel outputs could be connected to either the one or more speaker types or speaker sets of a first speaker cabinet or the one or more speaker types or speaker sets of the second speaker cabinet. The invention places no limitations on where the discrete channels are routed to or whether there is an equal number of speaker types or speaker sets as compared to channel outputs.

In another embodiment, the sound amplifier system described herein could be configured to have one speaker cabinet configured to contain at least two or more speaker types or speaker sets. In this configuration, there could be multiple inputs on the one speaker cabinet which then would be connected, independently, to the one or more speaker types or speaker sets. This configuration would allow the user to achieve the same result of switching channels and thereby switching speaker types or speaker sets all located within one speaker cabinet or enclosure.

In another embodiment, the sound amplifier systems described herein could be configured to allow the user to switch channels via a footswitch, a switch on the guitar amplifier, or remotely via electronic or fiber optic cable, wi-fi, Bluetooth, voice control, or other remote switching means known to those in the art. This channel switching may be performed at any time that is desirable for the user. A switch that is addressable remotely is called a remote controlled switch herein.

In another embodiment, the sound amplifier system may be configured to allow the user to connect additional speaker types or speaker sets, in one or more speaker cabinets or enclosures, to the speaker cabinets in the sound amplifier system. This would allow, for example, multiple speaker cabinets with different speaker types or speaker sets to be connected to the sound amplifier system where there are more speaker cabinets than channels. The sound amplifier system may have output jacks mirroring the input signal from the guitar amplifier such that an additional speaker cabinet or speaker cabinets may be connected. Connecting additional speakers to the output jack of the sound amplifier system as described herein is referred to as “daisy chaining.”

The additional speaker cabinets could also have additional output jacks so that even more speaker cabinets may be connected into the system. This is sometimes referred to as “daisy chaining” speaker cabinets. There is no limitation on the number of additional signal output jacks that may be configured on a speaker cabinet or enclosure. In another embodiment, the mirrored output jacks referred to above could also be configured to be switched on and off by the user, giving the user the option to decide which speaker cabinets, and thus which speaker types or speaker sets, are active and which are silent.

As stated earlier, in an embodiment where the sound amplifier system is configured to allow the user to switch or select which channel signal outputs are configured or connected to the various speaker types or speaker sets, the control of the selection may also be pre-configured to switch at a given time or moment. This control would allow a user the freedom to concentrate on their performance rather than the extra responsibility of controlling said switching. A switch which is capable of the pre-configuration is called a programmable switch herein.

It should be noted that with regards to many other embodiments, that other features, typically found on guitar amplifiers, such as effects and their controls and variables, gain controls and gain stages, pre-amp stages, volume controls, boost controls and boost and channels, multiple instrument inputs, effects loop returns and sends, tone stacks, EQ controls, digital or analog circuitry, power supply whether AC or DC, and other features not relating to the output of the signal to one or more speaker types or speaker sets, not stated, should not be considered a limitation of the invention described herein.

While exemplary embodiments have been described herein, it is expressly noted that these embodiments should not be construed as limiting, but rather that additions and modifications to what is expressly described herein also are included within the scope of the invention. Moreover, it is to be understood that the features of the various embodiments described herein are not mutually exclusive and may exist in various combinations and permutations, even if such combinations or permutations are not made express herein, without departing from the spirit and scope of the invention.

### Manufacturing

Each of the components of the sound amplifier system and related methods described herein may be manufactured and/or assembled in accordance with the conventional knowledge and level of a person having skill in the art.

While various details, features, and combinations are described in the illustrated embodiments, one having skill in the art will appreciate a myriad of possible alternative combinations and arrangements of the features disclosed herein. As such, the descriptions are intended to be enabling only, and non-limiting. Instead, the spirit and scope of the invention is set forth in the appended claims.

### First Through Fourth Illustrated Embodiments

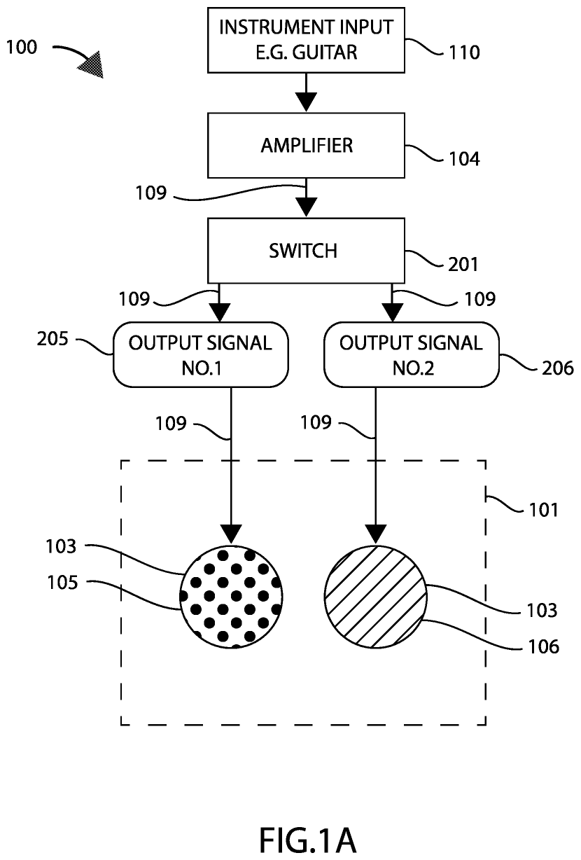

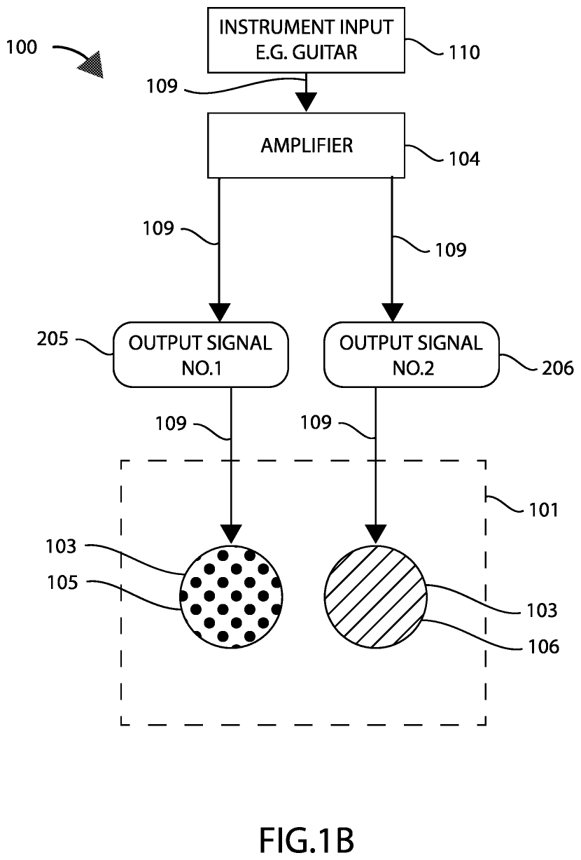

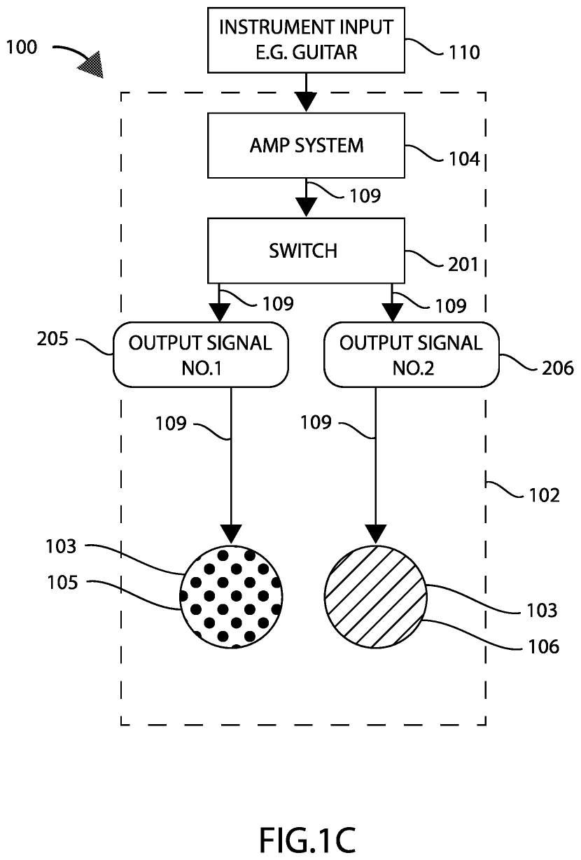

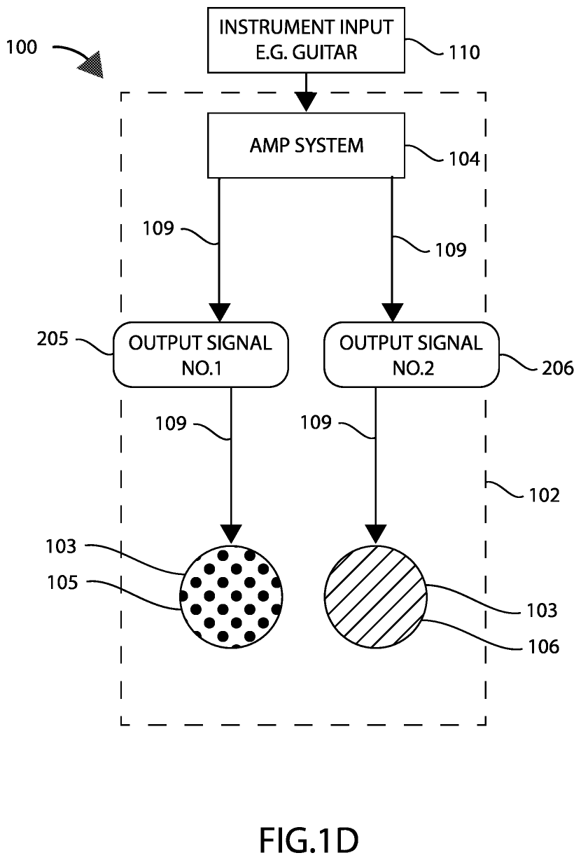

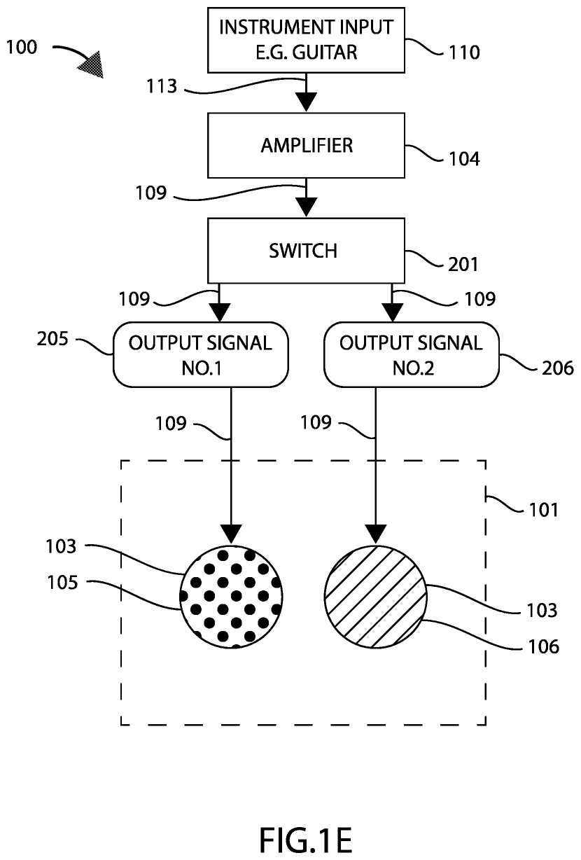

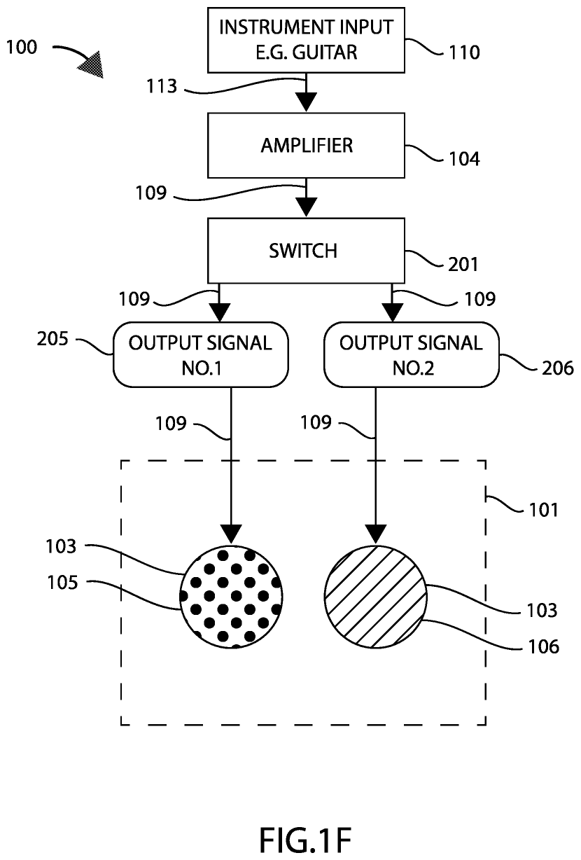

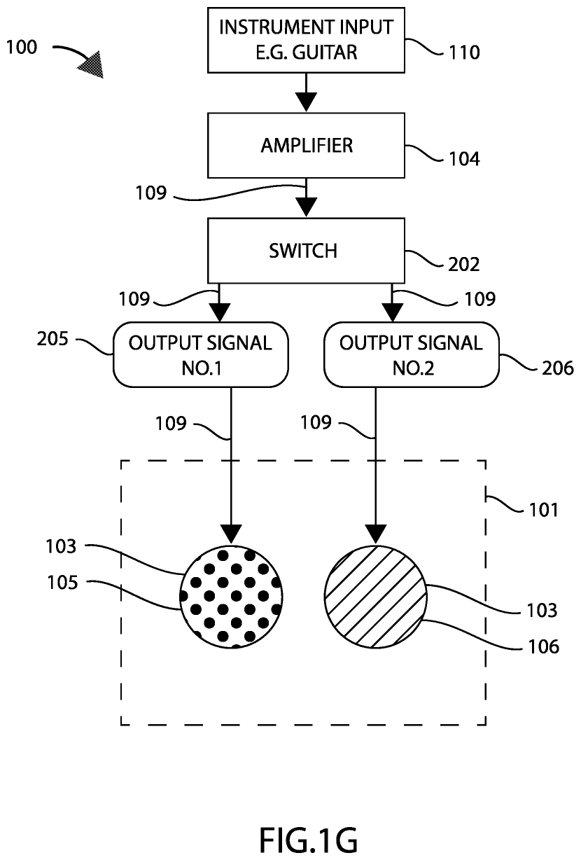

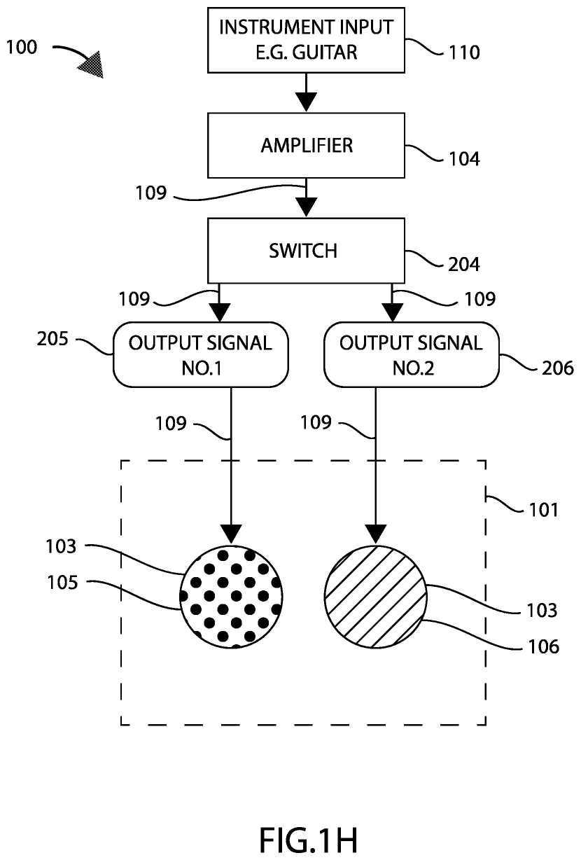

Shown in FIG. 1A-FIG. 1D are various embodiments of the signal wiring schematic for the sound amplification system (100). The instrument input (110) signal may be produced by an instrument and transmitted to the amplifier (104), in the head and cabinet embodiments, or to the amp system (112), in the combo amplifier (102) embodiments. In the first and third embodiments shown in FIG. 1A and FIG. 1C the signal is routed through a switch (201) which a user may use to select the signals, or channels, they wish. In the first and third embodiments the switch produces two output signals, output signal no.1 (205) and output signal no.2 (206). In the second and fourth embodiments shown in FIG. 1B and FIG. 1D the amplifier system produces output signal no.1 and output signal no.2. Other embodiments may have more than two output signals. The output signals are transmitted to the speakers (103). These signals may be transmitted through wiring (109) or through a wireless connection such as radio or Bluetooth. Output signal no.1 is transmitted to a speaker type 1 (105). Output signal no.2 is transmitted to a speaker type 2 (106). Other embodiments may have more than two speaker types. In the first and second embodiments the speakers are housed in a speaker cabinet (101). In the third and fourth embodiments the speakers are housed in a combo amplifier (102).

### Fifth Through Eighth Illustrated Embodiments

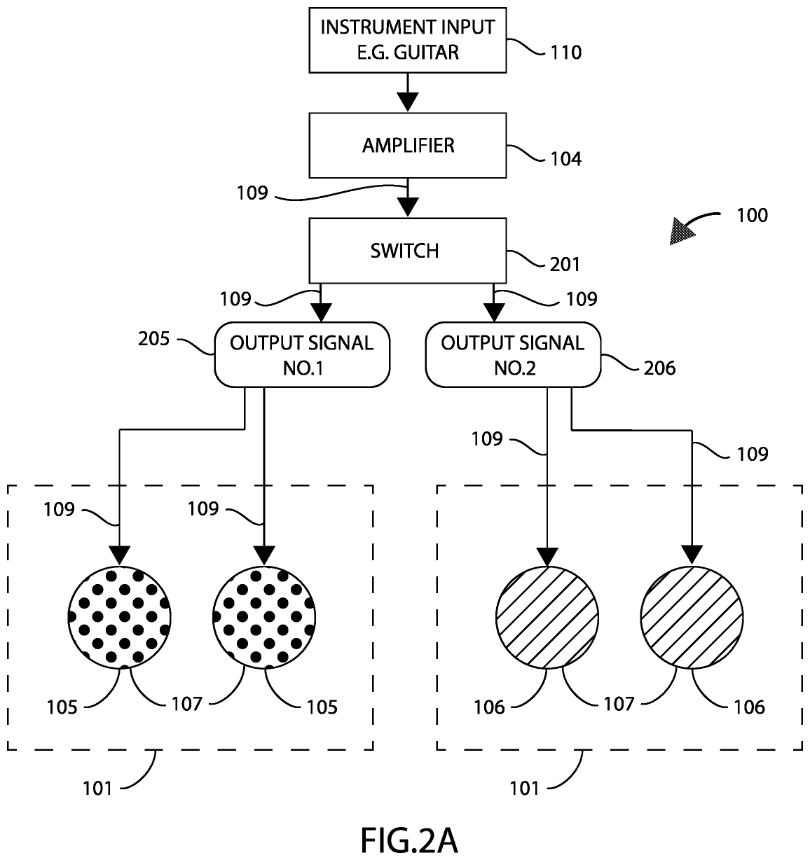

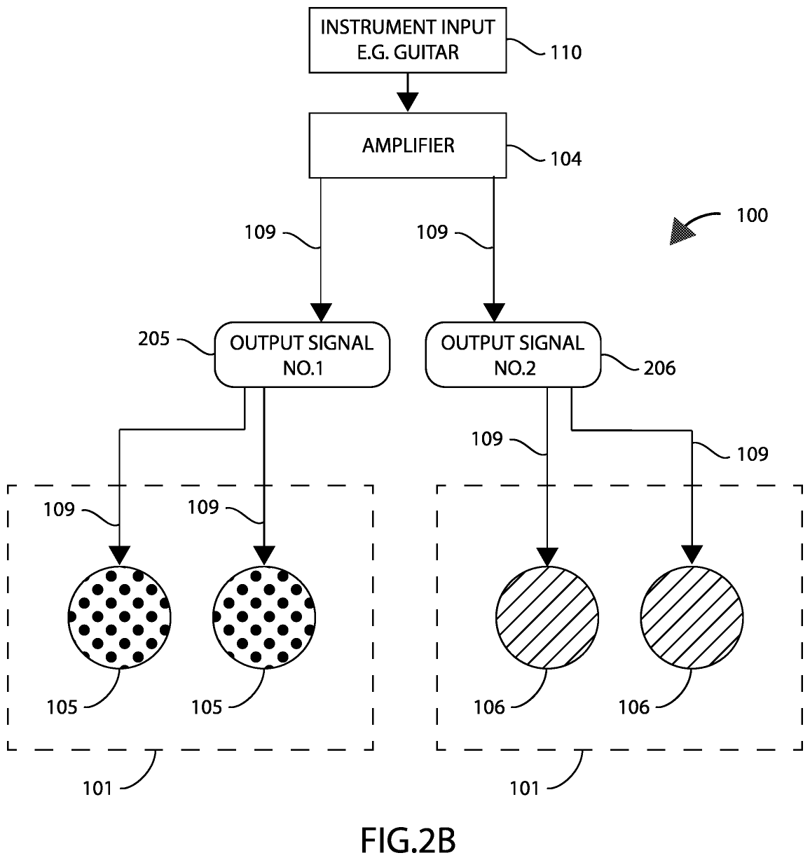

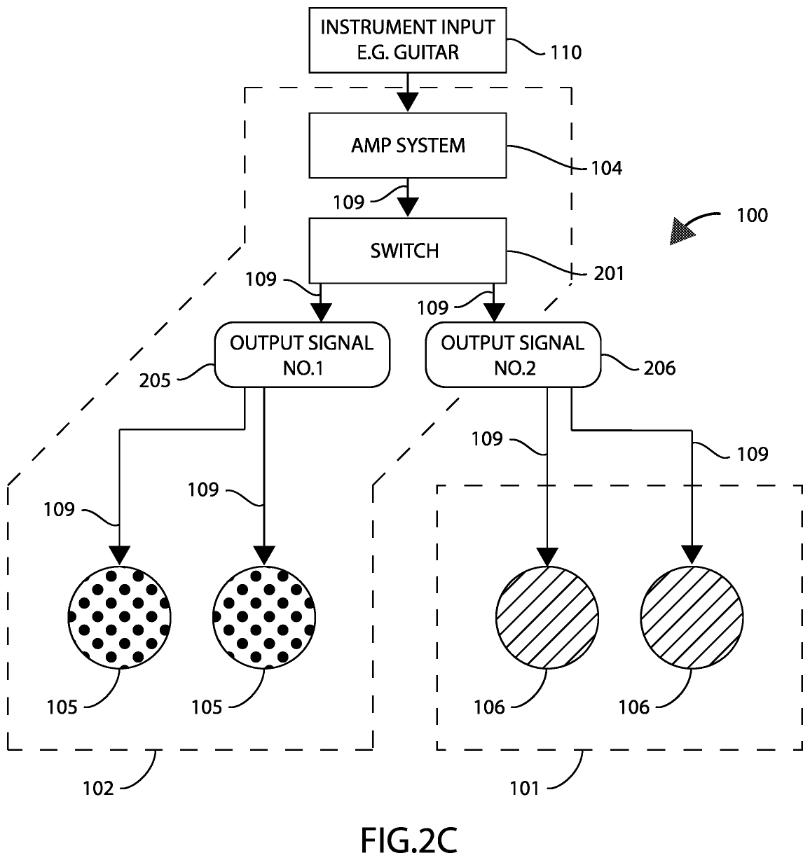

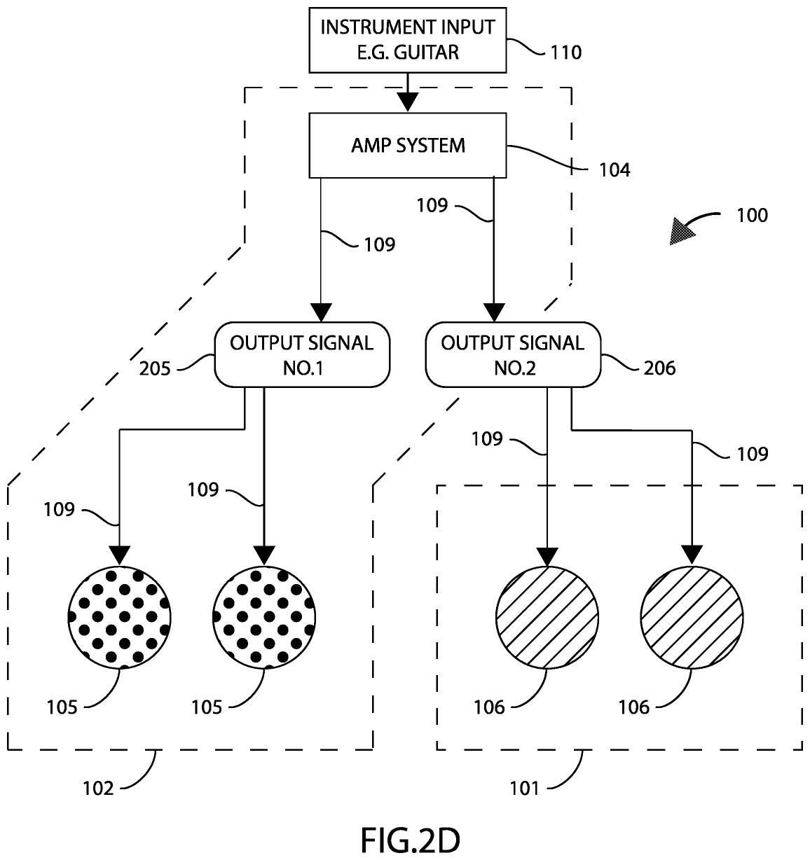

Shown in FIG. 2A-FIG. 2D are various embodiments of the signal wiring schematic for the sound amplification system (100). The instrument input (110) signal may be produced by an instrument and transmitted to the amplifier (104), in the head and cabinet embodiments, or amp system (112), in the combo amplifier (102) embodiments. In the fifth and seventh embodiments shown in FIG. 2A and FIG. 2C the signal is routed through a switch (201) which a user may use to select the signals, or channels, they wish. In the fifth and seventh embodiments the switch produces two output signals, output signal no.1 (205) and output signal no.2 (206). In the sixth and eighth embodiments shown in FIG. 2B and FIG. 2D the amplifier system produces output signal no.1 and output signal no.2. Other embodiments may have more than two output signals. The output signals are transmitted to the speakers (103). These signals may be transmitted through wiring (109) or through a wireless connection such as radio or Bluetooth. Output signal no.1 is transmitted to a speaker set (107) of speaker type 1 (105). Output signal no.2 is transmitted to a speaker set (107) of speaker type 2 (106). Other embodiments may have more than two speaker types. In the fifth and sixth embodiments shown in FIG. 2A and FIG. 2B the speaker set (107) of speaker type 1 (105) are housed in a speaker cabinet (101), and the speaker set of speaker type 2 (106) are housed in a speaker cabinet. In the fifth and sixth embodiments shown in FIG. 2C and FIG. 2D the speaker set (107) of speaker type 1 (105) are housed in a combo amplifier (102), and the speaker set of speaker type 2 (106) are housed in a speaker cabinet.

### Ninth Through Twelfth Illustrated Embodiments

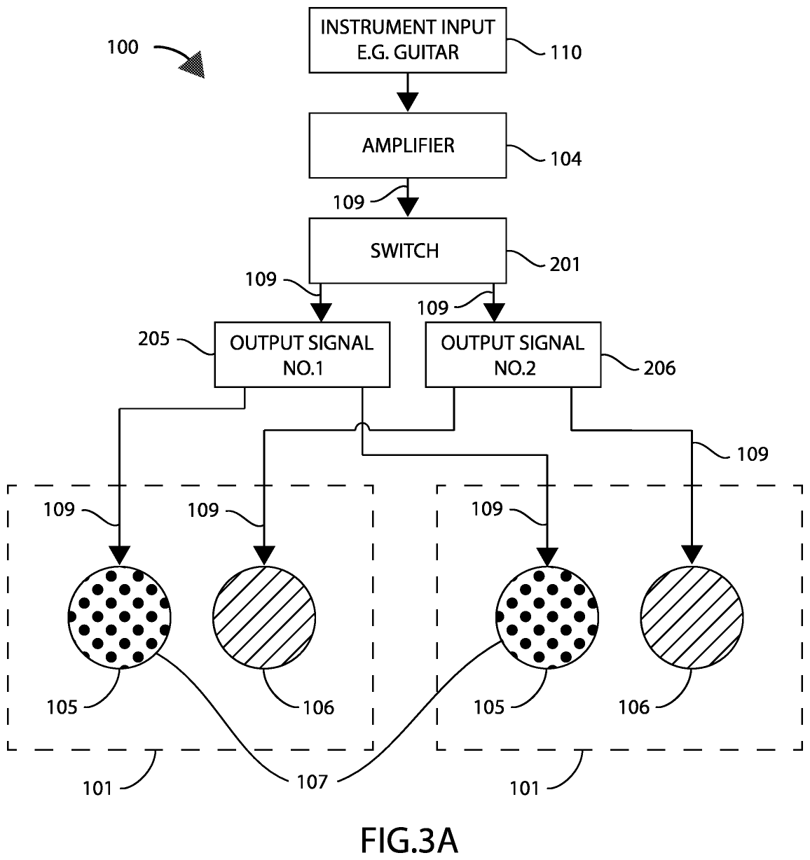

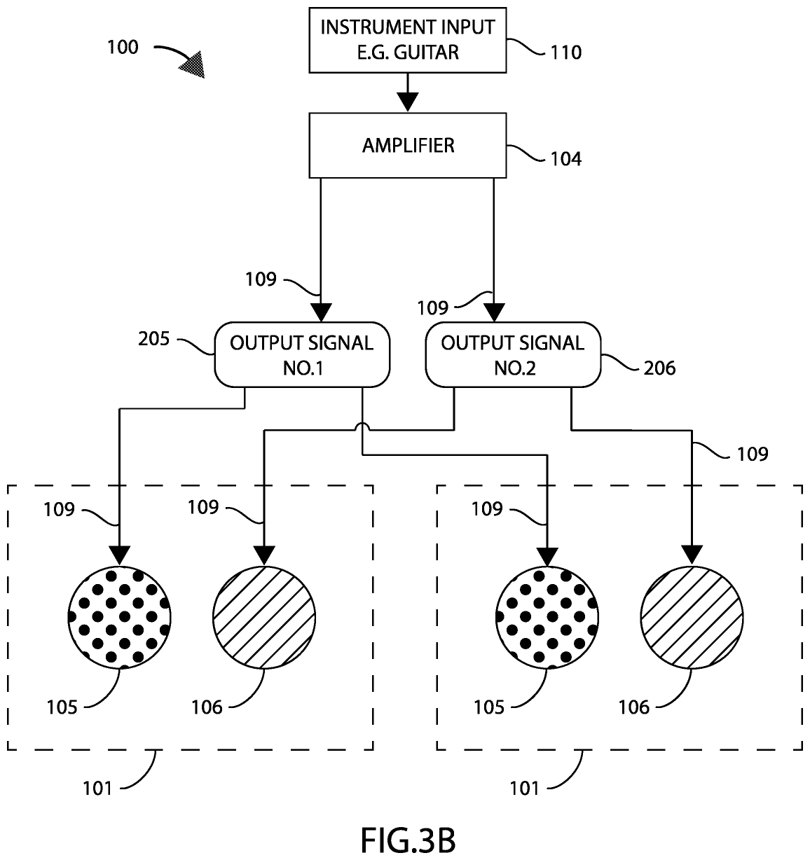

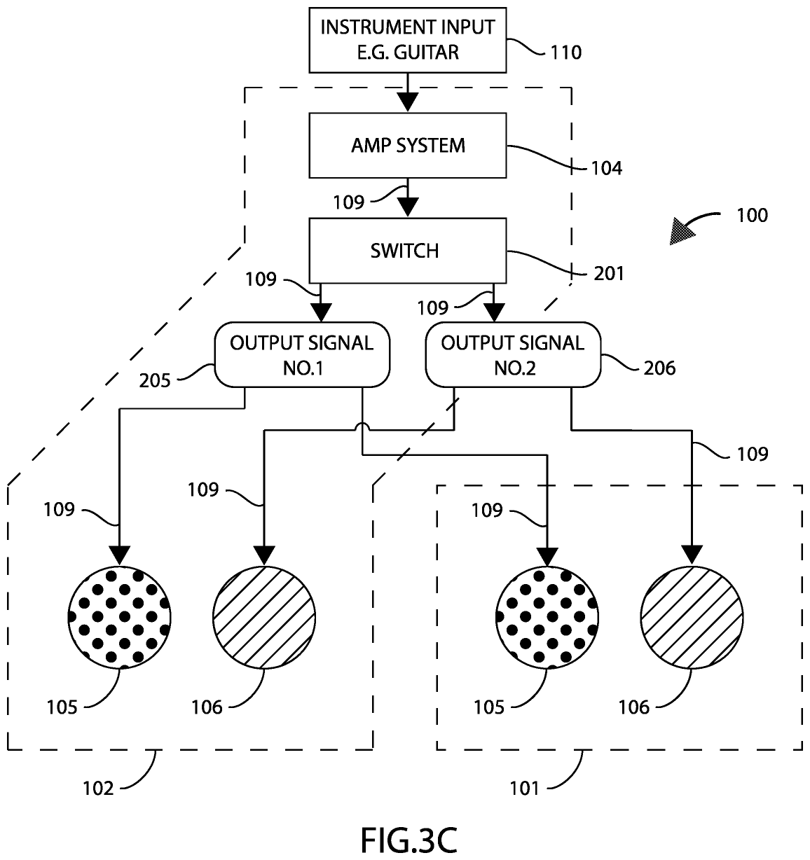

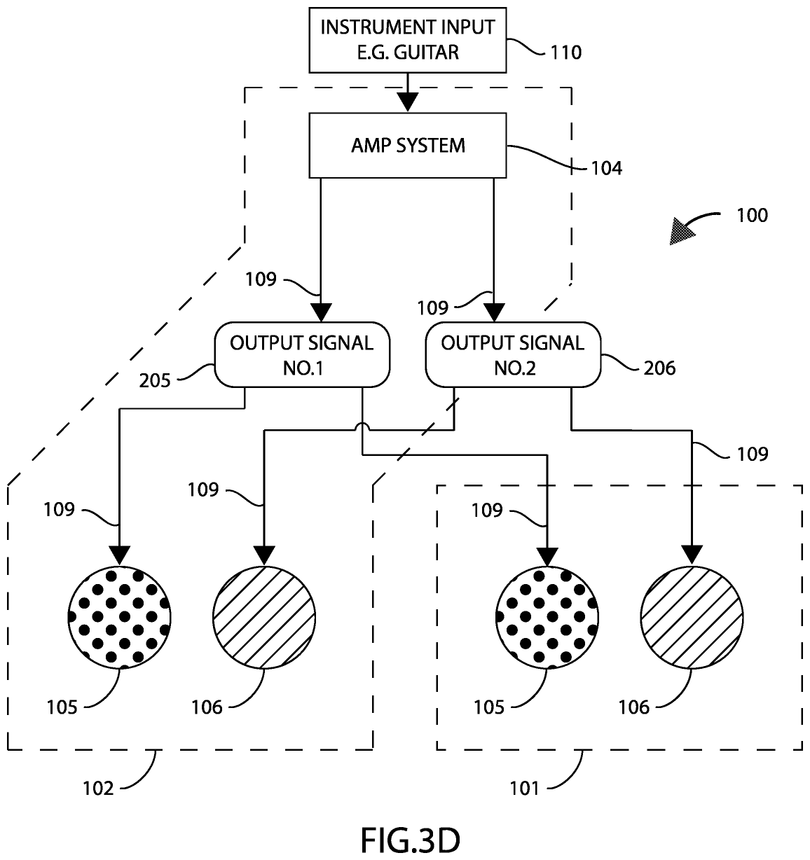

Shown in FIG. 3A-FIG. 3D are various embodiments of the signal wiring schematic for the sound amplification system (100). The instrument input (110) signal may be produced by an instrument and transmitted to the amplifier (104), in the head and cabinet embodiments, or amp system (112), in the combo amplifier (102) embodiments. In the ninth and eleventh embodiments shown in FIG. 3A and FIG. 3C the signal is routed through a switch (201) which a user may use to select the signals or channels they wish. In the ninth and eleventh embodiments, the switch produces two output signals, output signal no.1 (205) and output signal no.2 (206). In the tenth and twelfth embodiments shown in FIG. 3B and FIG. 3D, the amplifier system produces output signal no.1 and output signal no.2. The output signals are transmitted to the speakers (103). These signals may be transmitted through a wiring (109) or through a wireless connection such as radio or Bluetooth. Output signal no.1 is transmitted to a speaker set (107) of two speakers that are speaker type 1 (105). Output signal no.2 is transmitted to a speaker set (107) of two speakers that are speaker type 2 (106). Other embodiments may have more than two speaker types. In the ninth and tenth embodiments shown in FIG. 3A and FIG. 3B the one speaker type 1 is housed in a first speaker cabinet (101) and one speaker type 1 is housed in a second speaker cabinet. Similarly, in the ninth and tenth embodiments the one speaker type 2 is housed in a first speaker cabinet and one speaker type 2 is housed in a second speaker cabinet. In the eleventh and twelfth embodiments shown in FIG. 3C and FIG. 3D one speaker type 1 is housed in a combo amplifier (102) and one speaker type 1 is housed in a speaker cabinet. Similarly, in the eleventh and twelfth embodiments one speaker type 2 is housed in a combo amplifier and one speaker type 2 is housed in a speaker cabinet.

### Thirteenth Through Sixteenth Illustrated Embodiments

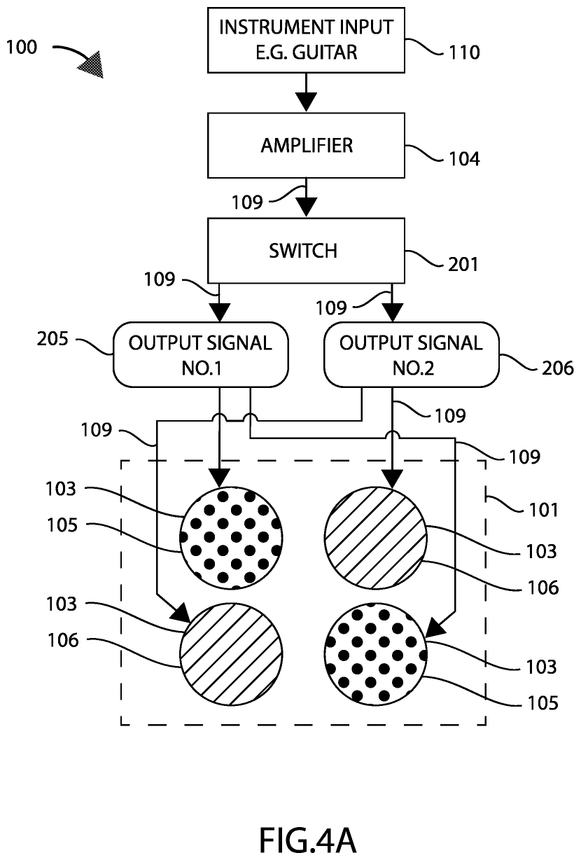

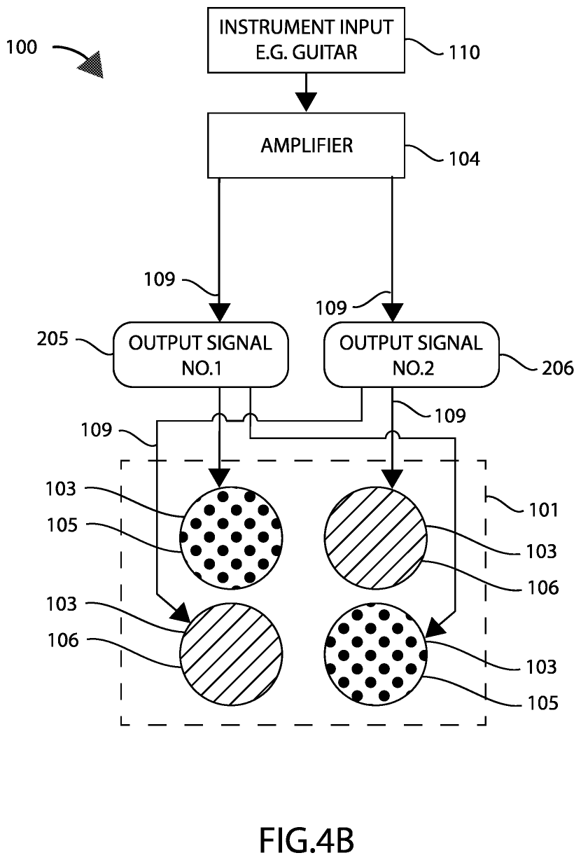

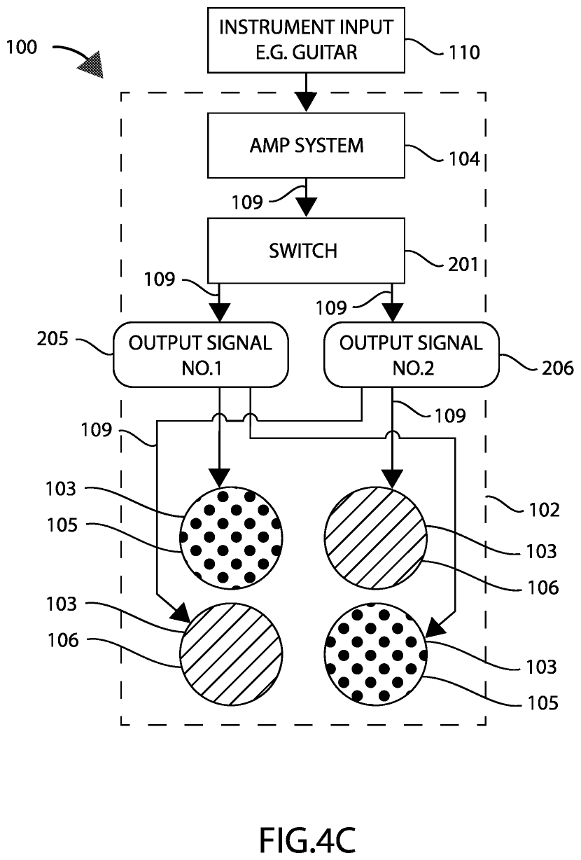

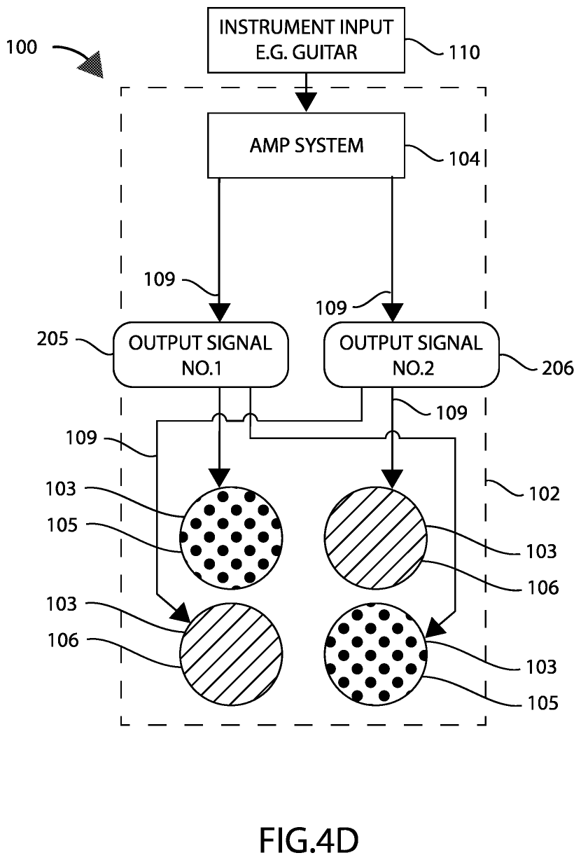

Shown in FIG. 4A-FIG. 4D are various embodiments of the signal wiring schematic for the sound amplification system (100). Output signal no.1 is transmitted to a speaker set (107) of two speakers that are speaker type 1 (105). Output signal no.2 is transmitted to a speaker set (107) of two speakers that are speaker type 2 (106). In the thirteenth and fourteenth embodiments shown in FIG. 4A and FIG. 4B two speaker type 1 speakers are housed in a speaker cabinet (101), and two speaker type 2 speakers are housed in the same speaker cabinet. In the fifteenth and sixteenth embodiments shown in FIG. 4C and FIG. 4D two speaker type 1 speakers are housed in a combo amplifier (102), and two speaker type 2 speakers are housed in the same combo amplifier.

### Seventeenth Through Twentieth Illustrated Embodiments

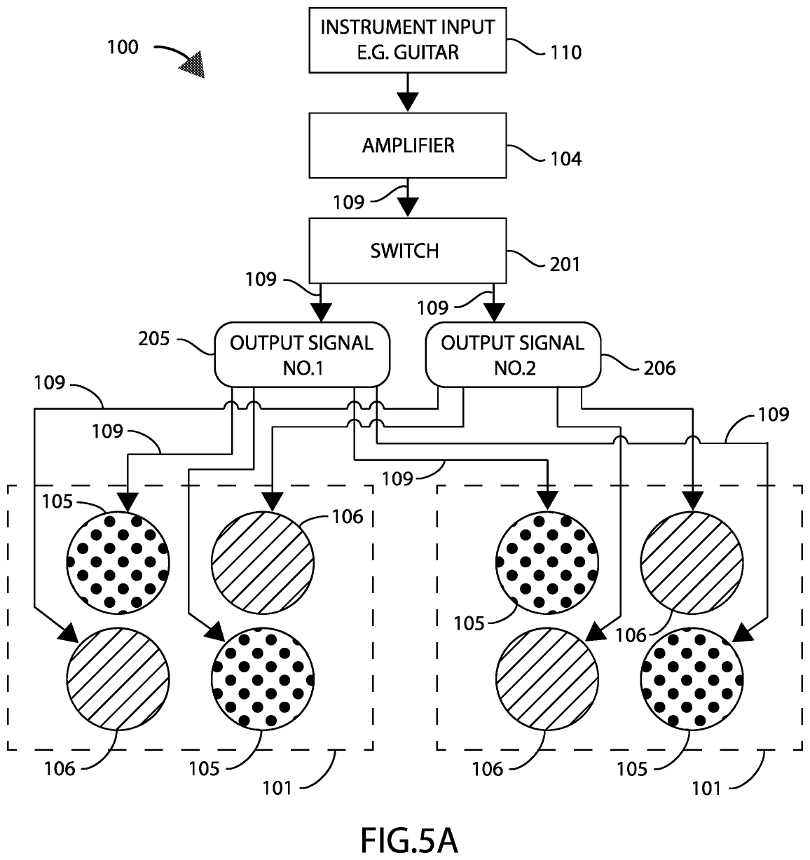

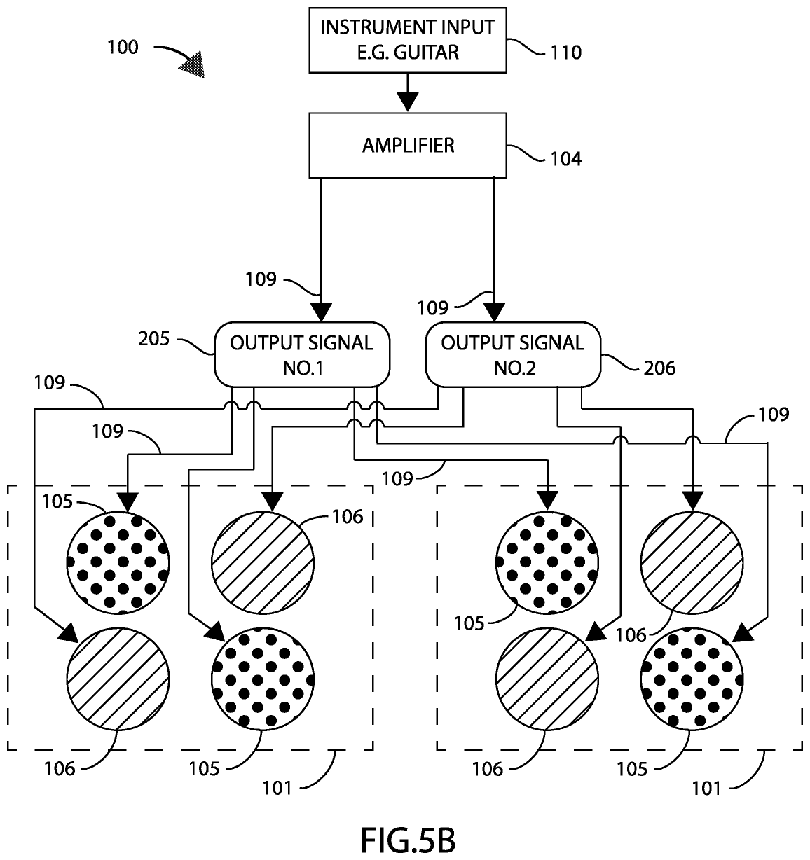

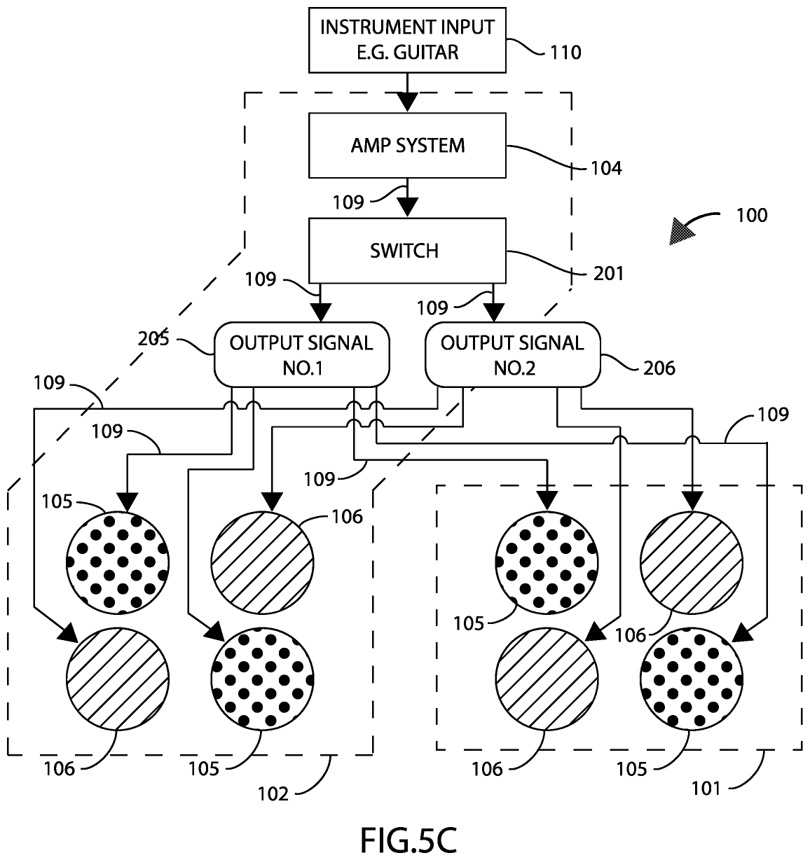

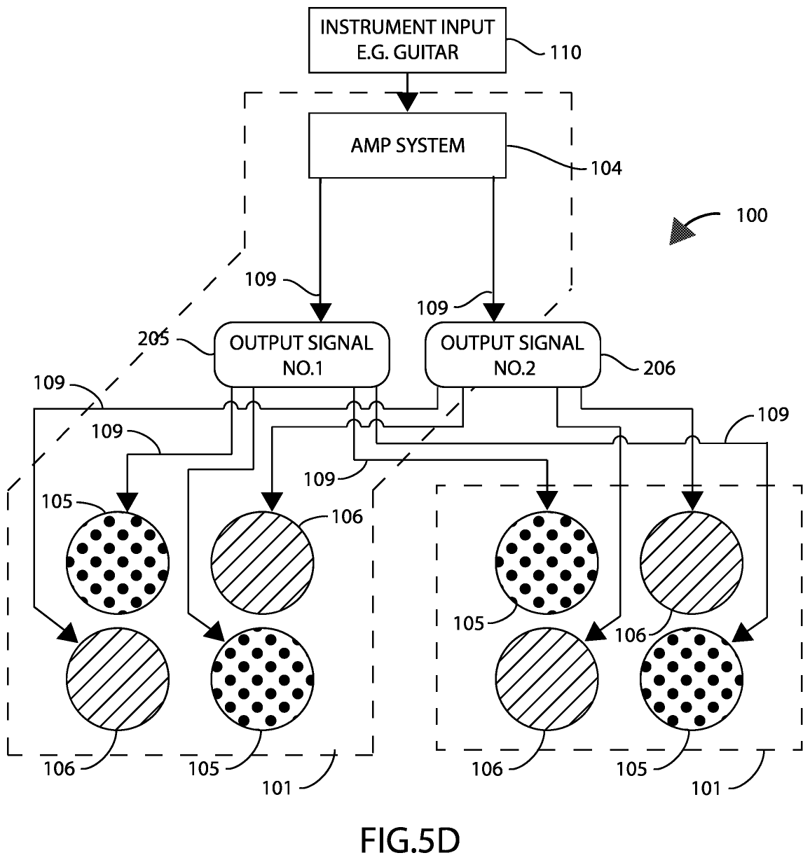

Shown in FIG. 5A-FIG. 5D are various embodiments of the signal wiring schematic for the sound amplification system (100). Output signal no.1 is transmitted to a speaker set (107) of four speakers that are speaker type 1 (105). Output signal no.2 is transmitted to a speaker set (107) of four speakers that are speaker type 2 (106). In the seventeenth and eighteenth embodiments shown in FIG. 5A and FIG. 5B two speaker type 1 speakers are housed in one speaker cabinet (101) and two speaker type 2 speakers are housed in another speaker cabinet. In the nineteenth and twentieth embodiments shown in FIG. 5C and FIG. 5D two speaker type 1 speakers are housed in a combo amplifier (102), and two speaker type 2 speakers are housed in a speaker cabinet.

### Second Illustrated Embodiment

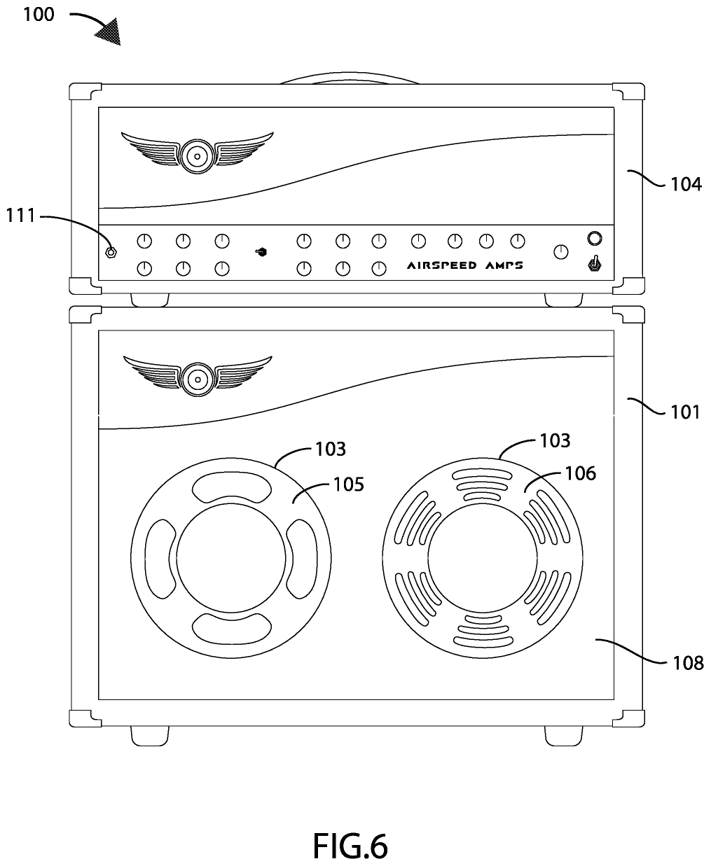

Shown in FIG. 6 is a second illustrated embodiment of the sound amplification system (100). The system has an amplifier (104) and a speaker cabinet (101). The speaker cabinet houses one speaker type 1 (105) speaker (103) and one speaker type 2 (106) speaker.

### Third Illustrated Embodiment

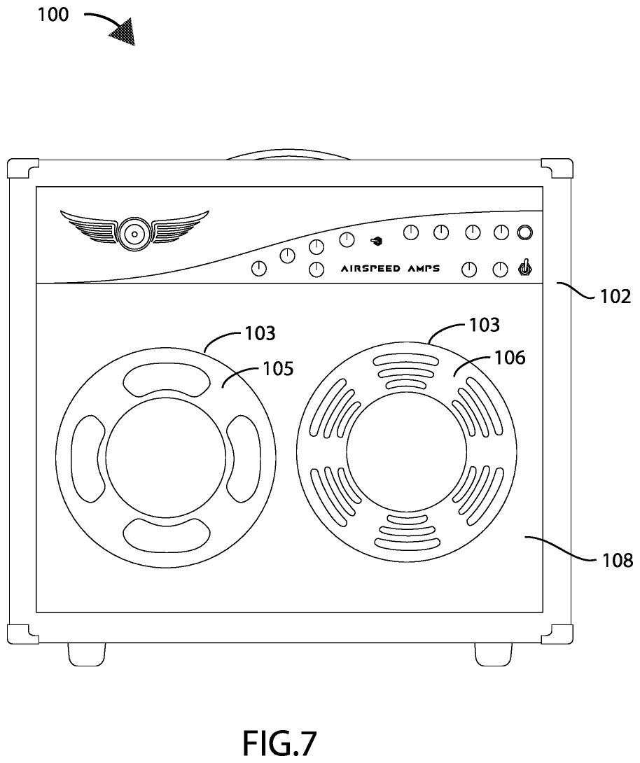

Shown in FIG. 7 is a third illustrated embodiment of the sound amplification system (100). The system uses a combo amplifier (102). The combo amplifier houses one speaker type no. 1 (105) speaker (103) and one speaker type 2 (106) speaker.

### Sixth Illustrated Embodiment

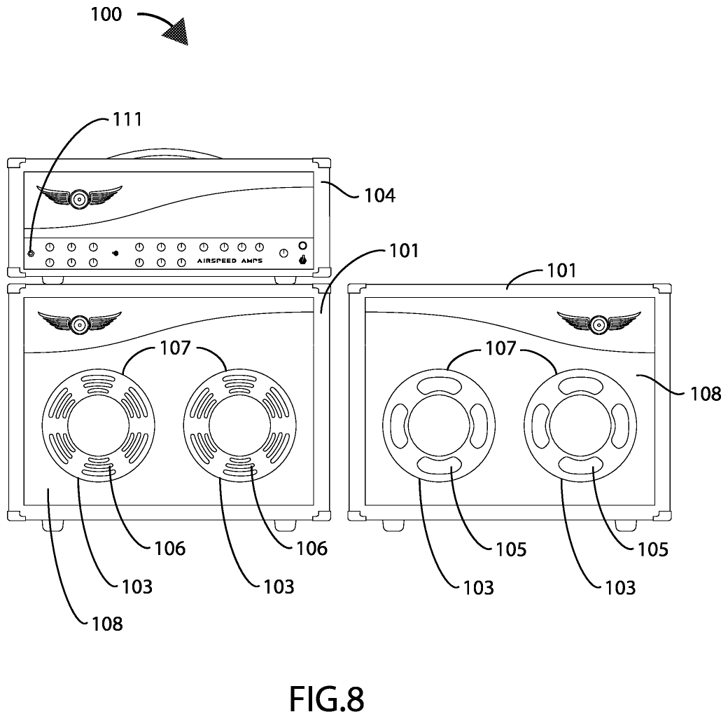

Shown in FIG. 8 is a sixth illustrated embodiment of the sound amplification system (100). The system uses two speaker cabinets (101) and an amplifier (102). One speaker cabinet houses two speaker type 1 (105) speakers (103). One speaker cabinet houses two speaker type 2 speakers.

### Twenty-First Illustrated Embodiment

Shown in FIG. 1E is a twenty-first illustrated embodiment of the sound amplifier system (100). The instrument input (110) is transmitted to the signal input receiver (111) via a wireless connection, for example via radio or Bluetooth. A wireless connection such as this can be applied to other embodiments.

### Twenty-Second Illustrated Embodiment

Shown in FIG. 1F is a twenty-second illustrated embodiment of the sound amplifier system (100). The output signal no.1 (205) and output signal no.2 (206) are transmitted to the speakers (103) via a wireless connection (113). Wireless connections such as these can be applied to other embodiments.

### Twenty-Third Illustrated Embodiment

Shown in FIG. 1G is a twenty-third illustrated embodiment of the sound amplifier system (100). The switch (201) used in this embodiment is a manually operated switch, called a manual switch (202). A manual switch can be applied to other embodiments.

### Twenty-Fourth Illustrated Embodiment

Shown in FIG. 1H is a twenty-third illustrated embodiment of the sound amplifier system (100). The switch (201) used in this embodiment is a programmable switch (203). A programmable switch can be applied to other embodiments.

### Twenty-Fifth Illustrated Embodiment

Shown in FIG. 1I is a twenty-third illustrated embodiment of the sound amplifier system (100). The switch (201) used in this embodiment is a remote controlled switch (204). A remote controlled switch can be applied to other embodiments.

### Twenty-Sixth Illustrated Embodiment

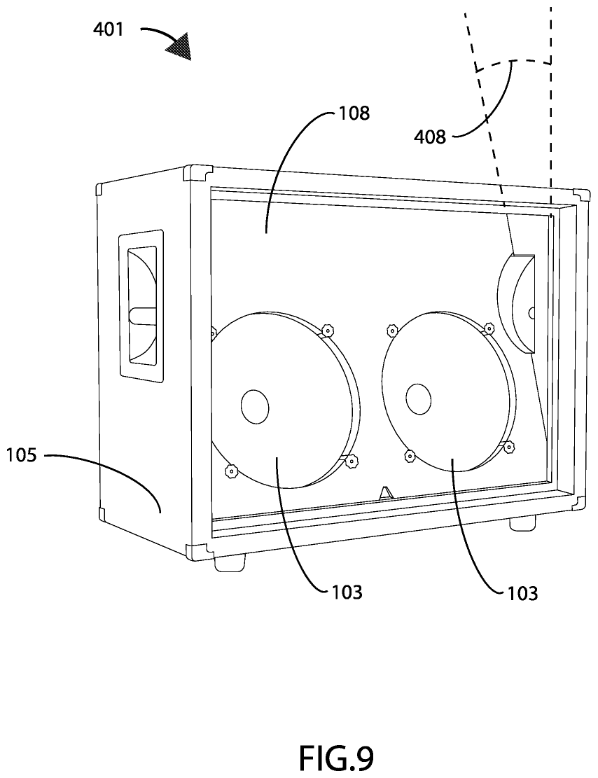

Shown in FIG. 9 is a sound amplifier system with articulating speakers (401). The Vertical speaker angle (408) is shown as degree of articulation about a horizontal speaker axis (405).

### Illustration of Planes

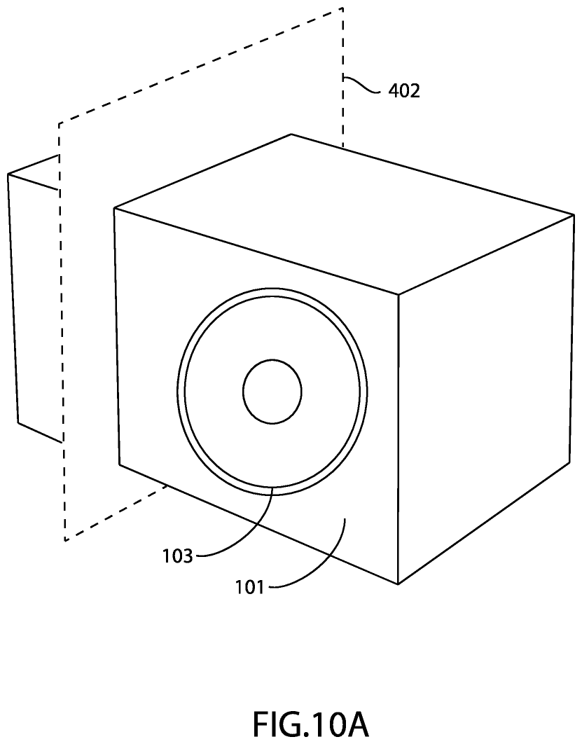

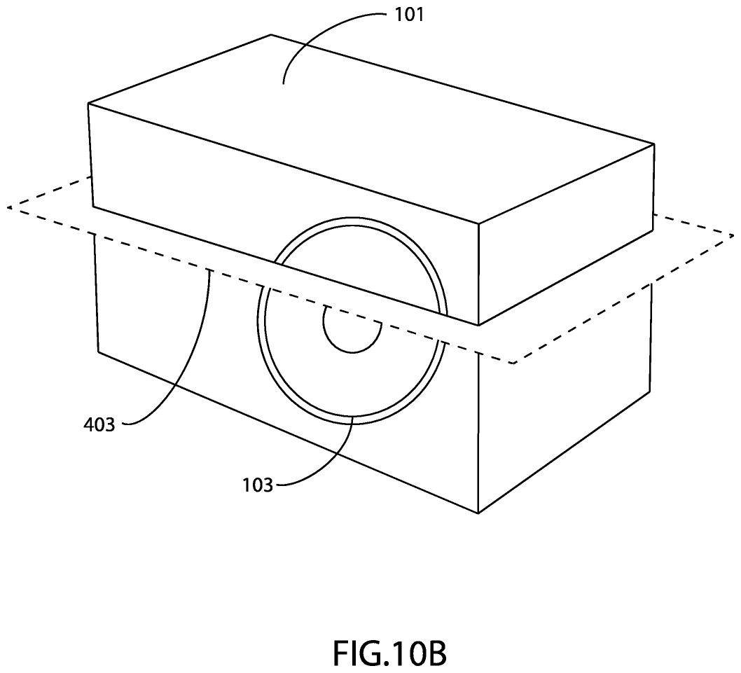

Shown in FIG. 10A-FIG. 10C are the three speaker planes. A left-right plane (402), an up-down plane (403), and a front-back plane (404) are identified.

### Twenty-Seventh Through Thirty-Third Illustrated Embodiments

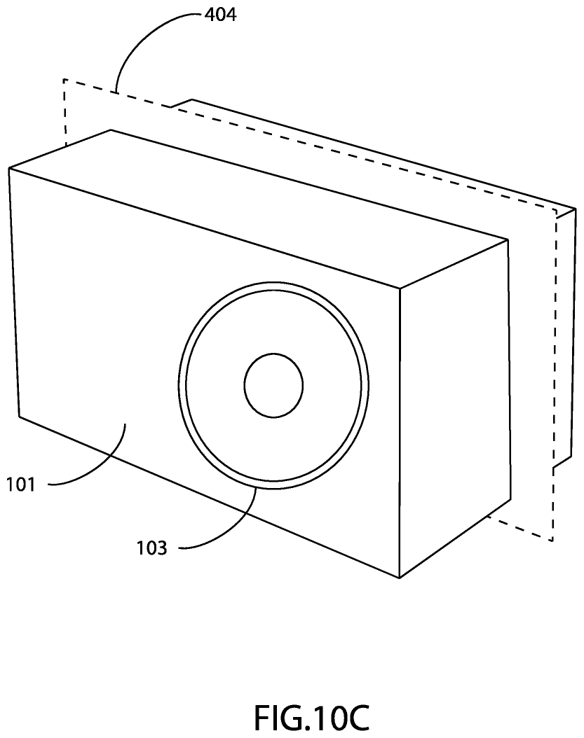

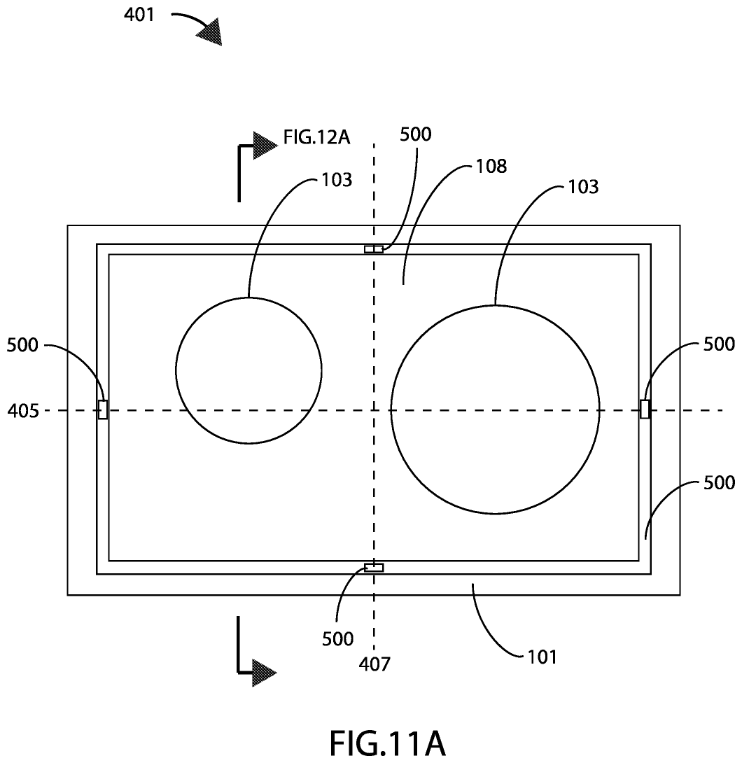

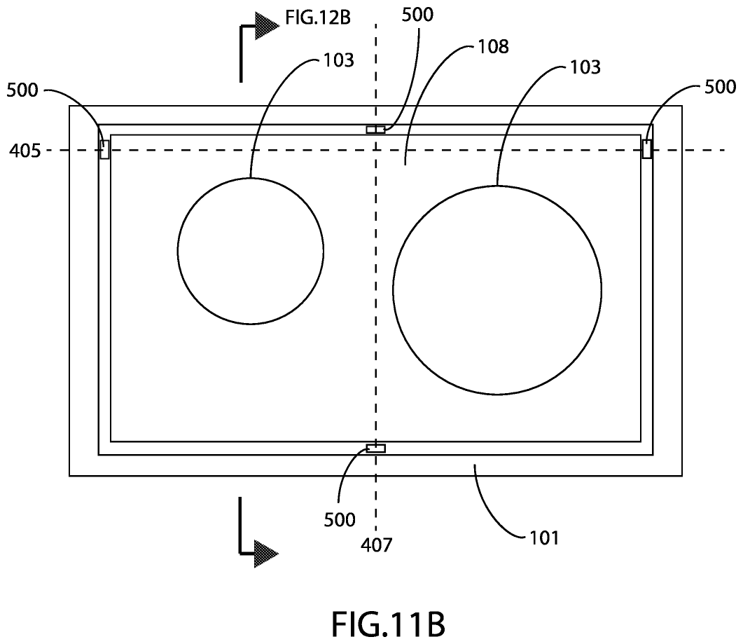

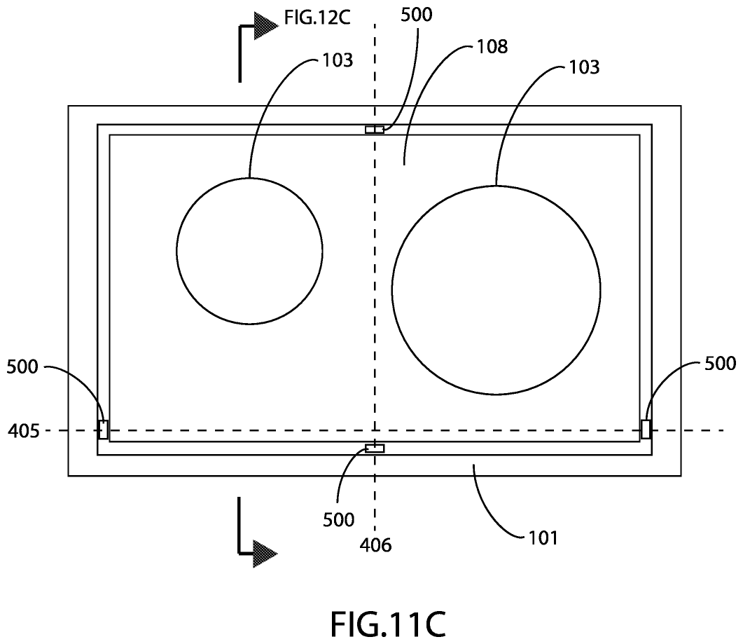

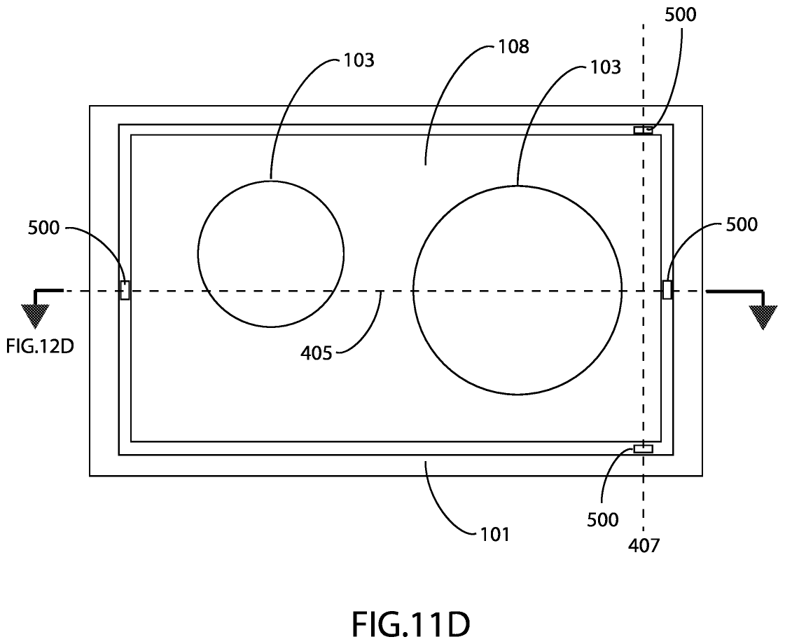

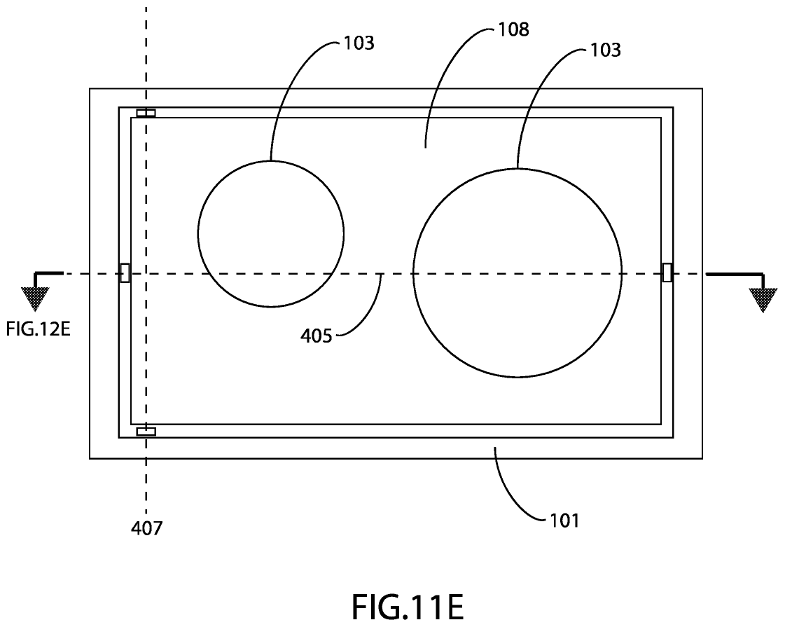

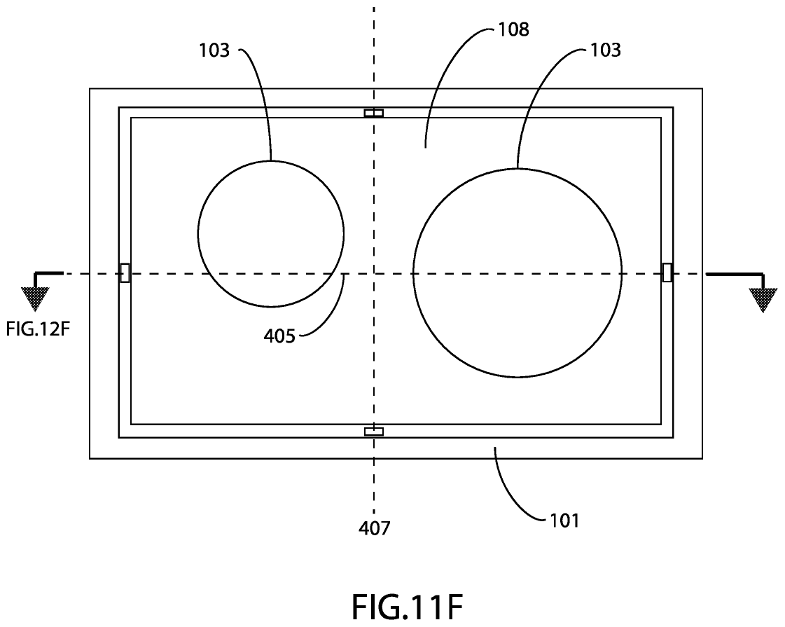

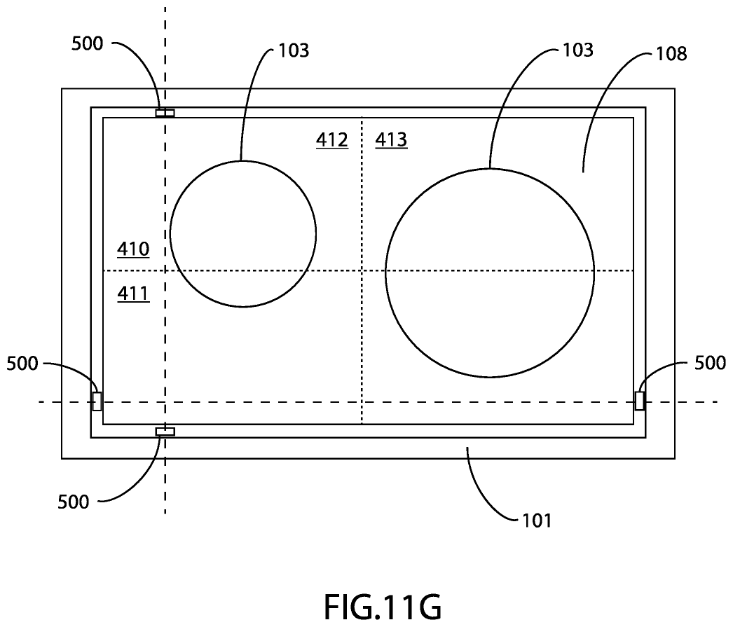

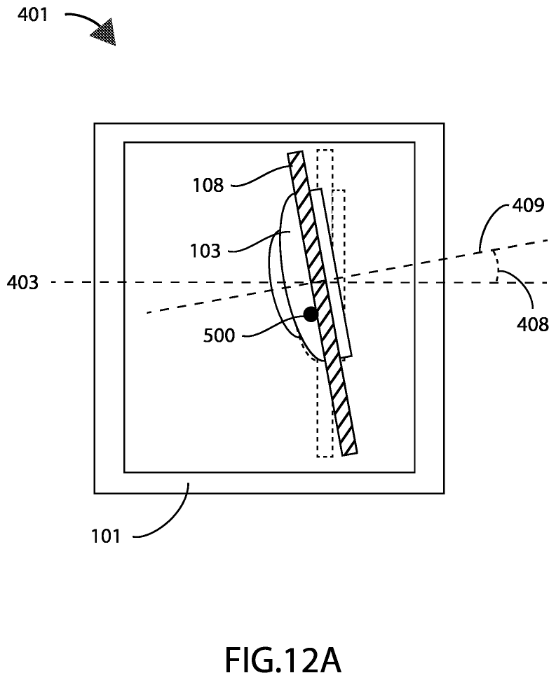

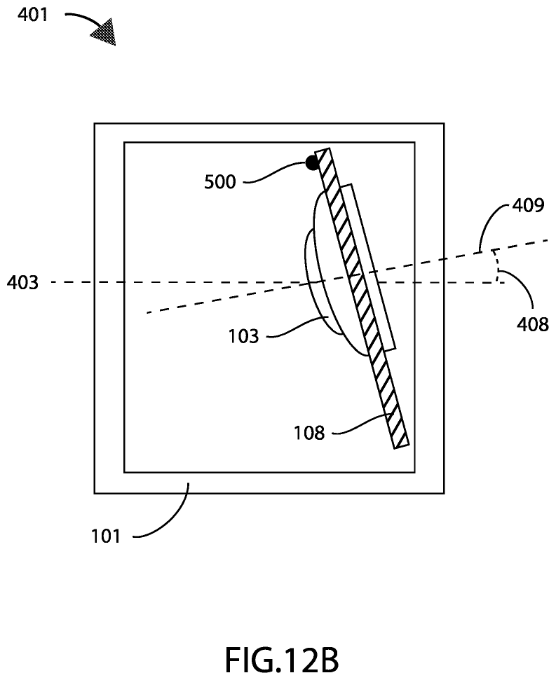

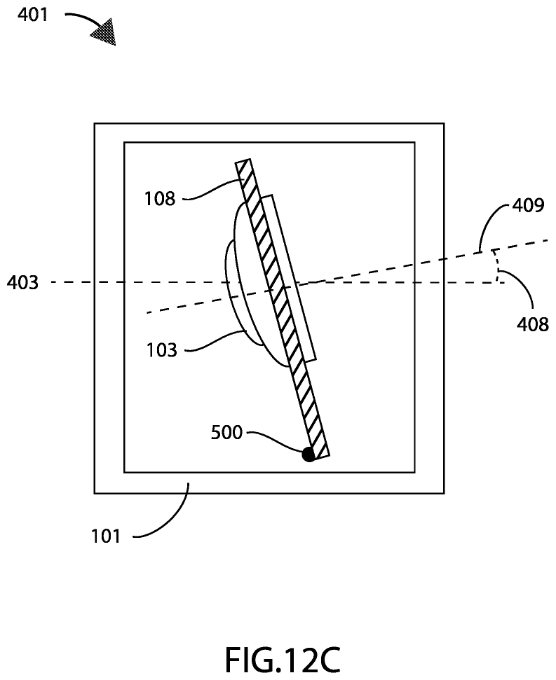

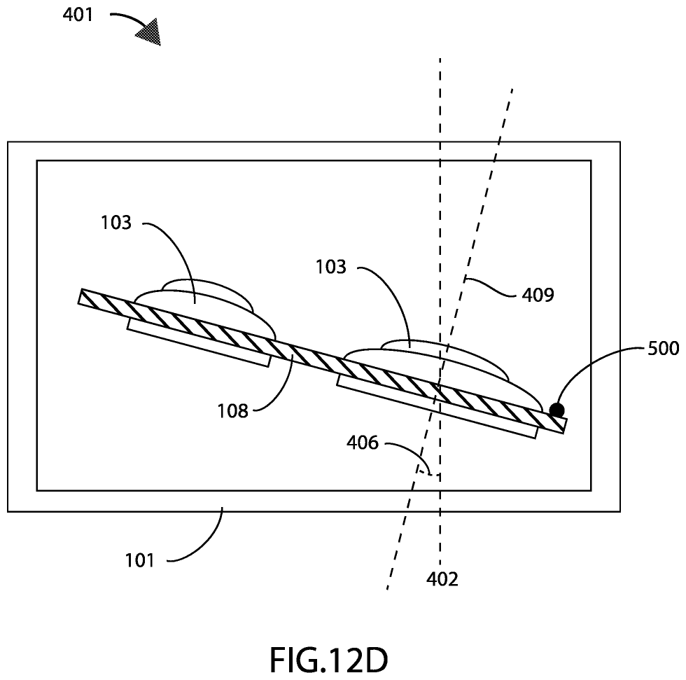

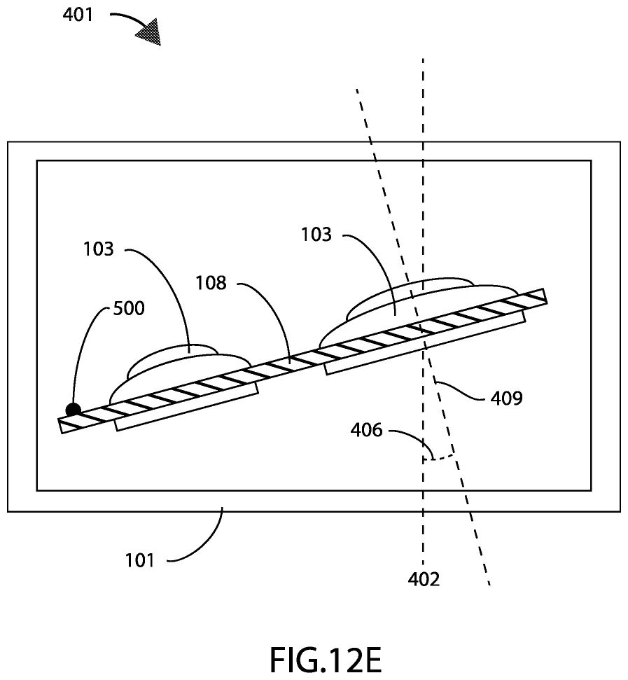

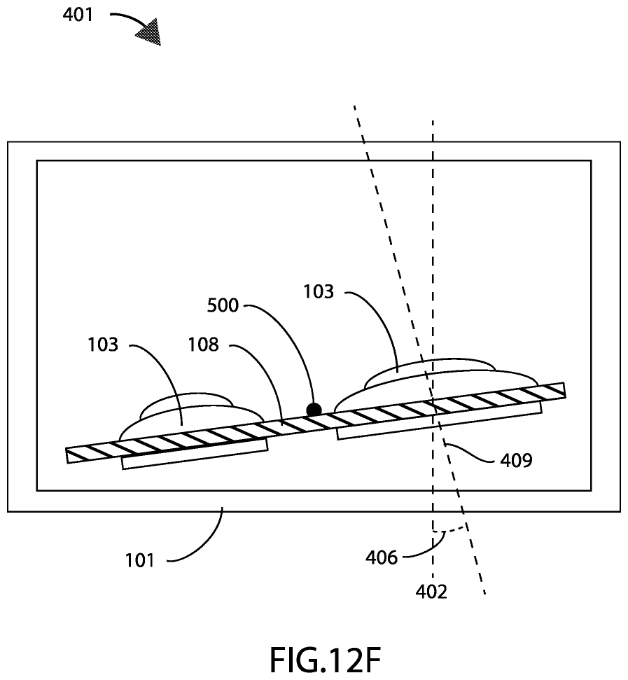

Shown in FIG. 11A-FIG. 12F are a variety of illustrated embodiments for sound amplifier systems with articulating speakers (401). The speaker angle adjusting system (500) is shown in a variety of configurations. In FIG. 11G the top half (410), bottom half (411), left half (412), and right half (413) of the speaker baffle are depicted. In FIG. 12A-FIG. 12C side sectional views of the sound amplifier system are shown in which the speaker direction (409) and vertical speaker angle (408) are identified. In FIG. 12D-FIG. 12F top sectional views of the sound amplifier system are shown in which the speaker direction (409) and horizontal speaker angle (406) are identified.

### Thirty-Fourth Illustrated Embodiment

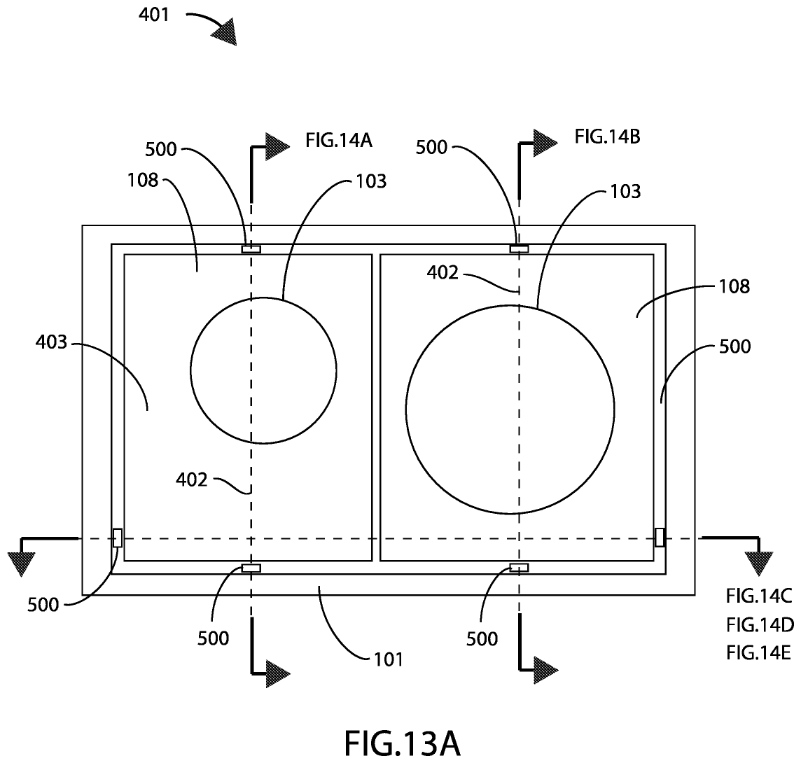

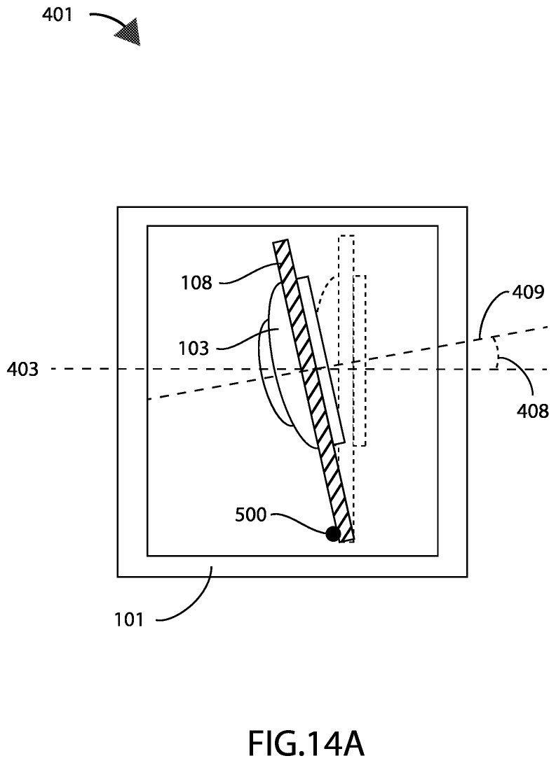

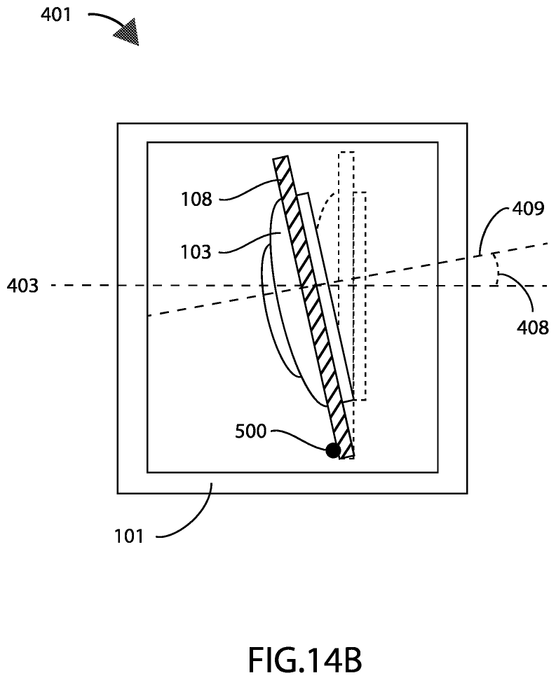

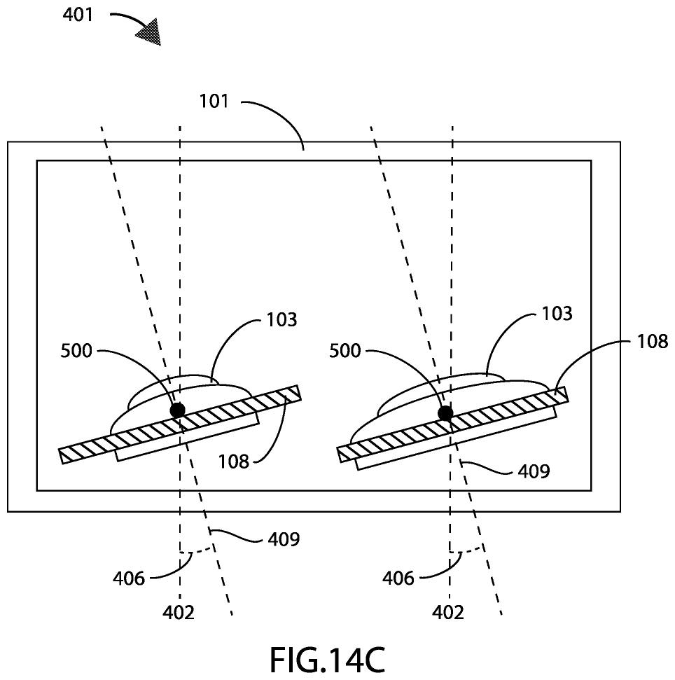

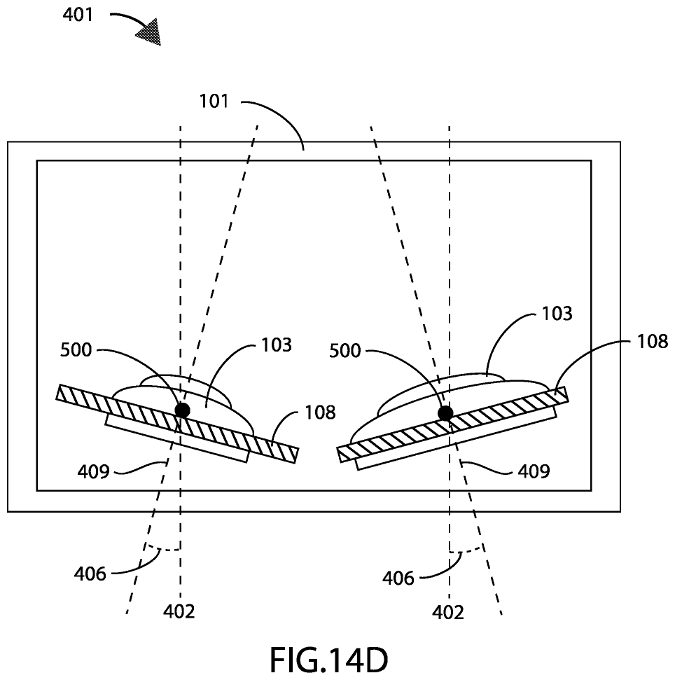

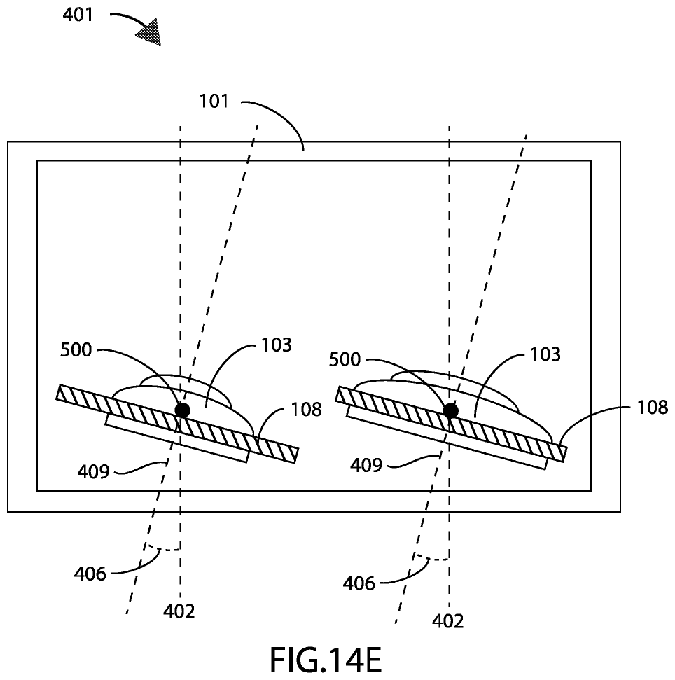

Shown in FIG. 13A-FIG. 14E is a thirty-fourth illustrated embodiment of the sound amplifier system with articulating speakers (401). The speaker angle adjusting system (500) is shown in a variety of configurations. In FIG. 14A-FIG. 14B side sectional views of the sound amplifier system are shown in which the speaker direction (409) and vertical speaker angle (408) are identified. In FIG. 14C-FIG. 14E top sectional views of the sound amplifier system are shown in which the speaker direction (409) and horizontal speaker angle (406) are identified.

### FEATURE LIST

Sound Amplifier System (100)
Speaker Cabinet (101)
Combo Amplifier (102)
Speaker (103)
Amplifier (104)
Speaker Type 1 (105)
Speaker Type 2 (106)
Speaker Set (107)
Speaker Baffle (108)
Wiring (109)
Instrument Input (110)
Signal Input Receiver (111)
Amp System (112)
Wireless Connection (113)
Switch (201)
Manual Switch (202)
Programmable Switch (203)
Remote Controlled Switch (204)
Output Signal No.1 (205)
Output Signal No.2 (206)
Sound Amplifier System with Articulating Speakers (401)
Left-Right Plane (402)
Up-Down Plane (403)
Front-Back Plane (404)
Horizontal Speaker Axis (405)
Horizontal Speaker Angle (406)
Vertical Speaker Axis (407)
Vertical Speaker Angle (408)
Speaker Direction (409)
Top Half (410)
Bottom Half (411)
Left Half (412)
Right Half (413)
Speaker Angle Adjusting System (500)
Manual Speaker Angle Adjusting System (501)
Manual Actuator (502)
Motor Speaker Angle Adjusting System (503)
Motor Controller (504)
Motor Remote Controller (505)
Variable Angle Baffle Configuration (506)

What is claimed is:

1. A sound amplifier system, comprising:
a. A speaker cabinet; the speaker cabinet comprising an enclosure configured to rest on a horizontal surface.
b. A speaker baffle; the speaker baffle comprising a substrate onto which a plurality of speakers are attached, the speaker baffle generally facing outward away from the speaker cabinet,
c. A plurality of speakers; the plurality of speakers being attached to the speaker baffle,
d. A speaker angle adjusting system; the speaker angle adjusting system being an articulatable structure that is attached between the speaker baffle and the speaker cabinet such that the speaker baffle may be articulated with respect to the speaker cabinet.

2. The sound amplifier system of claim 1, wherein:
a. A single speaker is attached to the speaker baffle.

3. The sound amplifier system of claim 1, wherein:
a. Two speakers are attached to the speaker baffle.

4. The sound amplifier system of claim 1, further comprising:
a. A motor; the motor being mechanically coupled with the speaker angle adjusting system such that, when activated, the motor articulates the speaker baffle, changing the speaker direction of the speakers mounted to the speaker baffle.

5. The sound amplifier system of claim 1, wherein:
a. The speaker baffle articulates about a horizontal speaker axis.

6. The sound amplifier system of claim 1, wherein:
a. The speaker baffle articulates about a vertical speaker axis.

7. The sound amplifier system of claim 1, further comprising:
a. A second speaker baffle and a second speaker angle adjusting system; the second speaker baffle comprising a substrate onto which a plurality of speakers are attached, the second speaker baffle generally facing outward away from the speaker cabinet, the second speaker angle adjusting system being an articulatable structure that is attached between the second speaker baffle and the speaker cabinet such that the second speaker baffle may be articulated with respect to the speaker cabinet.

8. The sound amplifier system of claim 5, wherein:
a. The speaker angle adjusting system is attached between the top half of the speaker baffle and the speaker cabinet.

9. The sound amplifier system of claim 5, wherein:
a. The speaker angle adjusting system is attached between the bottom half of the speaker baffle and the speaker cabinet.

10. The sound amplifier system of claim 5, wherein:
a. The speaker baffle can articulate between 0 degrees, which is parallel to an up-down plane, and 30 degrees above the up-down plane, enabling the vertical speaker angle to be adjusted between 0 to 30 degrees.

11. The sound amplifier system of claim 6, wherein:
a. The speaker angle adjusting system is attached between the left half of the speaker baffle and the speaker cabinet.

12. The sound amplifier system of claim 6, wherein:
a. The speaker angle adjusting system is attached between the right half of the speaker baffle and the speaker cabinet.

13. The sound amplifier system of claim 6, wherein:
a. The speaker baffle can articulate between negative 30 degrees with respect to a left-right plane and positive 30 degrees with respect to the left-right plane, enabling the horizontal speaker angle to be adjusted between negative 30 degrees to positive 30 degrees.

14. The sound amplifier system of claim 7, wherein:
a. The speaker baffle articulates about a horizontal speaker axis, and the second speaker baffle articulates about a horizontal speaker axis.

15. The sound amplifier system of claim 7, wherein:
a. The speaker baffle articulates about a vertical speaker axis, and the second speaker baffle articulates about a vertical speaker axis.

16. The sound amplifier system of claim 14, wherein:
a. The speaker angle adjusting system is attached between the top half of the second speaker baffle and the speaker cabinet.

17. The sound amplifier system of claim 14, wherein:
a. The speaker angle adjusting system is attached between the bottom half of the second speaker baffle and the speaker cabinet.

18. The sound amplifier system of claim 15, wherein:
a. The speaker angle adjusting system is attached between the left half of the speaker baffle and the speaker cabinet.

19. The sound amplifier system of claim 15, wherein:
a. The speaker angle adjusting system is attached between the right half of the speaker baffle and the speaker cabinet.

20. A sound amplifier system, comprising:
a. A speaker cabinet; the speaker cabinet comprising an enclosure configured to rest on a horizontal surface.
b. A speaker baffle; the speaker baffle comprising a substrate onto which a plurality of speakers are attached, the speaker baffle generally facing outward away from the speaker cabinet,
c. A plurality of speakers; the plurality of speakers being attached to the speaker baffle,
d. A speaker angle adjusting system; the speaker angle adjusting system being an articulatable structure that is attached between the speaker baffle and the speaker cabinet such that the speaker baffle may be articulated with respect to the speaker cabinet, the speaker angle adjusting system configured to articulate the speaker baffle about a horizontal speaker axis between 0 degrees, which is parallel to an up-down plane, and 30 degrees above the up-down plane, enabling the vertical speaker angle to be adjusted between 0 to 30 degrees.
